(19) United States
(12) Patent Application Publication
(10) Pub. No.: US 2023/0127257 A1
(43) Pub. Date: Apr. 27, 2023

(54) METHOD FOR REMOVING A DEVICE USING AN EPITAXIAL LATERAL OVERGROWTH TECHNIQUE

(71) Applicant: The Regents of the University of California, Oakland, CA (US)

(72) Inventors: Takeshi Kamikawa, Kyoto (JP); Masahiro Araki, Yokkaichi-city, Mie (JP); Srinivas Gandrothula, Santa Barbara, CA (US)

(73) Assignee: The Regents of the University of California, Oakland, CA (US)

(21) Appl. No.: 17/912,976

(22) PCT Filed: Apr. 19, 2021
(86) PCT No.: PCT/US2021/027914

§ 371 Date: Sep. 20, 2022

Related U.S. Application Data
(60) Provisional application No. 63/011,698, filed on Apr. 17, 2020.

(51) Int. Cl. H01L 21/02; H01L 33/32

(52) U.S. Cl. CPC H01L 21/02647; H01L 21/0254; H01L 21/02389; H01L 21/02458; H01L 21/02642; H01L 33/32

(57) ABSTRACT

An epitaxial lateral overgrowth (ELO) of a III-nitride layer is used to cover a growth restrict mask deposited on a substrate, wherein the III-nitride ELO layer is grown with a low V/III ratio of less than 500 resulting in high-speed lateral growth as compared to low-speed vertical growth. The III-nitride ELO layer contains a large amount of impurities, over 1 × 10¹⁸ cm⁻³, which result in the III-nitride ELO layer comprising a coloring layer. The coloring layer absorbs light from an active region due to the large amount of impurities. When a bar of device layers is removed from the substrate, at least a portion of the coloring layer is removed from the bar. The elimination of the coloring layer reduces absorption losses, which makes the device characteristics improve.

### CROSS REFERENCE TO RELATED APPLICATIONS

This application claims the benefit under 35 U.S.C. Section 119(e) of the following co-pending and commonly-assigned application:
U.S. Provisional Application Serial No. 63/011,698, filed on Apr. 17, 2020, by Takeshi Kamikawa, Masahiro Araki and Srinivas Gandrothula, entitled “METHOD FOR REMOVING A DEVICE USING AN EPITAXIAL LATERAL OVERGROWTH TECHNIQUE,” attorneys’ docket number G&C 30794.0762USP1 (UC 2020-706-1);
which application is incorporated by reference herein.

This application is related to the following co-pending and commonly-assigned applications:
U.S. Utility Pat. Application No. 16/608,071, filed on Oct. 24, 2019, by Takeshi Kamikawa, Srinivas Gandrothula, Hongjian Li and Daniel A. Cohen, entitled “METHOD OF REMOVING A SUBSTRATE,” attorney’s docket number 30794.0653USWO (UC 2017-621-1), which application claims the benefit under 35 U.S.C. Section (c) of co-pending and commonly-assigned PCT International Pat. Application No. PCT/US18/31393, filed on May 7, 2018, by Takeshi Kamikawa, Srinivas Gandrothula, Hongjian Li and Daniel A. Cohen, entitled “METHOD OF REMOVING A SUBSTRATE,” attorney’s docket number 30794.0653WOU1 (UC 2017-621-2), which application claims the benefit under 35 U.S.C. Section (e) of co-pending and commonly-assigned U.S. Provisional Pat. Application No. 62/502,205, filed on May 5, 2017, by Takeshi Kamikawa, Srinivas Gandrothula, Hongjian Li and Daniel A. Cohen, entitled “METHOD OF REMOVING A SUBSTRATE,” attorney’s docket number 30794.0653USP1 (UC 2017-621-1);
U.S. Utility Pat. Application No. 16/642,298, filed on Feb. 20, 2020, by Takeshi Kamikawa, Srinivas Gandrothula and Hongjian Li, entitled “METHOD OF REMOVING A SUBSTRATE WITH A CLEAVING TECHNIQUE,” attorney’s docket number 30794.0659USWO (UC 2018-086-2), which application claims the benefit under 35 U.S.C. Section (c) of co-pending and commonly-assigned PCT International Pat. Application No. PCT/US18/51375, filed on Sep. 17, 2018, by Takeshi Kamikawa, Srinivas Gandrothula and Hongjian Li, entitled “METHOD OF REMOVING A SUBSTRATE WITH A CLEAVING TECHNIQUE,” attorney’s docket number 30794.0659WOU1 (UC 2018-086-2), which application claims the benefit under 35 U.S.C. Section (e) of co-pending and commonly-assigned U.S. Provisional Pat. Application No. 62/559,378, filed on Sep. 15, 2017, by Takeshi Kamikawa, Srinivas Gandrothula and Hongjian Li, entitled “METHOD OF REMOVING A SUBSTRATE WITH A CLEAVING TECHNIQUE,” attorney’s docket number 30794.0659USP1 (UC 2018-086-1);
U.S. Utility Pat. Application No. 16/978,493, filed on Sep. 4, 2020, by Takeshi Kamikawa, Srinivas Gandrothula and Hongjian Li, entitled “METHOD OF FABRICATING NONPOLAR AND SEMIPOLAR DEVICES USING EPITAXIAL LATERAL OVERGROWTH,” attorney’s docket number 30794.0680USWO (UC 2018-427-2), which application claims the benefit under 35 U.S.C. Section (c) of co-pending and commonly-assigned PCT International Pat. Application No. PCT/US19/25187, filed on Apr. 1, 2019, by Takeshi Kamikawa, Srinivas Gandrothula and Hongjian Li, entitled “METHOD OF FABRICATING NONPOLAR AND SEMIPOLAR DEVICES USING EPITAXIAL LATERAL OVERGROWTH,” attorney’s docket number 30794.0680WOU1 (UC 2018-427-2), which application claims the benefit under 35 U.S.C. Section 119(e) of co-pending and commonly-assigned U.S. Provisional Pat. Application Serial No. 62/650,487, filed on Mar. 30, 2018, by Takeshi Kamikawa, Srinivas Gandrothula, and Hongjian Li, entitled “METHOD OF FABRICATING NONPOLAR AND SEMIPOLAR DEVICES BY USING LATERAL OVERGROWTH,” attorney docket number G&C 30794.0680USP1 (UC 2018-427-1);
U.S. Utility Pat. Application No. 17/048,383, filed on Oct. 16, 2020, by Takeshi Kamikawa and Srinivas Gandrothula, entitled “METHOD FOR DIVIDING A BAR OF ONE OR MORE DEVICES,” attorney’s docket number 30794.0681USWO (UC 2018-605-2), which application claims the benefit under 35 U.S.C. Section (c) of co-pending and commonly-assigned PCT International Pat. Application No. PCT/US19/32936, filed on May 17, 2019, by Takeshi Kamikawa and Srinivas Gandrothula, entitled “METHOD FOR DIVIDING A BAR OF ONE OR MORE DEVICES,” attorney’s docket number 30794.0681WOU1 (UC 2018-605-2), which application claims the benefit under 35 U.S.C. Section (e) of co-pending and commonly-assigned U.S. Provisional Application Serial No. 62/672,913, filed on May 17, 2018, by Takeshi Kamikawa and Srinivas Gandrothula, entitled “METHOD FOR DIVIDING A BAR OF ONE OR MORE DEVICES,” attorneys’ docket number G&C 30794.0681USP1 (UC 2018-605-1);
U.S. Utility Pat. Application No. 17/049,156, filed on Oct. 20, 2020, by Srinivas Gandrothula and Takeshi Kamikawa, entitled “METHOD OF REMOVING SEMICONDUCTING LAYERS FROM A SEMICONDUCTING SUBSTRATE,” attorney’s docket number 30794.0682USWO (UC 2018-614-2), which application claims the benefit under 35 U.S.C. Section (c) of co-pending and commonly-assigned PCT International Pat. Application No. PCT/US 19/34686, filed on May 30, 2019, by Srinivas Gandrothula and Takeshi Kamikawa, entitled “METHOD OF REMOVING SEMICONDUCTING LAYERS FROM A SEMICONDUCTING SUBSTRATE,” attorney’s docket number 30794.0682WOU1 (UC 2018-614-2), which application claims the benefit under 35 U.S.C. Section (e) of co-pending and commonly-assigned U.S. Provisional Application Serial No. 62/677,833, filed on May 30, 2018, by Srinivas Gandrothula and Takeshi Kamikawa, entitled “METHOD OF REMOVING SEMICONDUCTING LAYERS FROM A SEMICONDUCTING SUBSTRATE,” attorneys’ docket number G&C 30794.0682USP1 (UC 2018-614-1);
U.S. Utility Pat. Application No. 17/285,827, filed on Apr. 15, 2021, by Takeshi Kamikawa and Srinivas Gandrothula, entitled “METHOD OF OBTAINING A SMOOTH SURFACE WITH EPITAXIAL LATERAL OVERGROWTH,” attorney’s docket number 30794.0693USWO (UC 2019-166-2), which application claims the benefit under 35 U.S.C. Section (c) of co-pending and commonly-assigned PCT International Pat. Application No. PCT/US19/59086, filed on Oct. 31, 2019, by Takeshi Kamikawa and Srinivas Gandrothula, entitled “METHOD OF OBTAINING A SMOOTH SURFACE WITH EPITAXIAL LATERAL OVERGROWTH,” attorney’s docket number 30794.0693WOU1 (UC 2019-166-2), which application claims the benefit under 35 U.S.C. Section (e) of co-pending and commonly-assigned U.S. Provisional Application Serial No. 62/753,225, filed on Oct. 31, 2018, by Takeshi Kamikawa and Srinivas Gandrothula, entitled “METHOD OF OBTAINING A SMOOTH SURFACE WITH EPITAXIAL LATERAL OVERGROWTH,” attorneys’ docket number G&C 30794.0693USP1 (UC 2019-166-1);
PCT International Pat. Application No. PCT/US20/13934, filed on Jan. 16, 2020, by Takeshi Kamikawa, Srinivas Gandrothula and Masahiro Araki, entitled “METHOD FOR REMOVAL OF DEVICES USING A TRENCH,” attorney’s docket number 30794.0713WOU1 (UC 2019-398-2), which application claims the benefit under 35 U.S.C. Section (e) of co-pending and commonly-assigned U.S. Provisional Application Serial No. 62/793,253, filed on Jan. 16, 2019, by Takeshi Kamikawa, Srinivas Gandrothula and Masahiro Araki, entitled “METHOD FOR REMOVAL OF DEVICES USING A TRENCH,” attorneys’ docket number G&C 30794.0713USP1 (UC 2019-398-1);
PCT International Pat. Application No. PCT/US20/20647, filed on Mar. 2, 2020, by Takeshi Kamikawa and Srinivas Gandrothula, entitled “METHOD FOR FLATTENING A SURFACE ON AN EPITAXIAL LATERAL GROWTH LAYER,” attorney’s docket number 30794.0720WOU1 (UC 2019-409-2), which application claims the benefit under 35 U.S.C. Section (e) of co-pending and commonly-assigned U.S. Provisional Application Serial No. 62/812,453, filed on Mar. 1, 2019, by Takeshi Kamikawa and Srinivas Gandrothula, entitled “METHOD FOR FLATTENING A SURFACE ON AN EPITAXIAL LATERAL GROWTH LAYER,” attorneys’ docket number G&C 30794.0720USP1 (UC 2019-409-1);
PCT International Pat. Application No. PCT/US20/22430, filed on Sep. 17, 2020, by Takeshi Kamikawa, Srinivas Gandrothula and Masahiro Araki, entitled “METHOD FOR REMOVING A BAR OF ONE OR MORE DEVICES USING SUPPORTING PLATES,” attorney’s docket number 30794.0724WOU1 (UC 2019-416-2), which application claims the benefit under 35 U.S.C. Section (e) of co-pending and commonly-assigned U.S. Provisional Application Serial No. 62/817,216, filed on Mar. 12, 2019, by Takeshi Kamikawa, Srinivas Gandrothula and Masahiro Araki, entitled “METHOD FOR REMOVING A BAR OF ONE OR MORE DEVICES USING SUPPORTING PLATES,” attorneys’ docket number G&C 30794.0724USP1 (UC 2019-416-1);
all of which applications are incorporated by reference herein.

### BACKGROUND OF THE INVENTION

### 1. Field of the Invention

This invention relates to a method for removing devices from a substrate using an epitaxial lateral overgrowth (ELO) technique.

### 2. Description of the Related Art

Many researchers have used the ELO technique with III-nitride layers and hetero-substrates, such as sapphire, silicon carbide, etc., in order to reduce defect density in the III-nitride layers. This invention uses the ELO technique for removing devices comprised of III-nitride layers from a substrate, as well as reducing defect density.

One ELO technique uses a growth restrict mask which has one or more opening areas. The lateral growth of the III-nitride layer, which starts at the opening areas of the growth restrict mask, is very slow. Generally, the period of the opening areas of the growth restrict mask are set to be about 10 µm - 20 µm, in order to obtain a flat layer on the hetero-substrate by embedding the growth restrict mask. However, a narrow period results in devices made by the ELO technique containing a coalescence region. Therefore, the ELO technique has been avoided when producing devices due to the narrow period problem.

Thus, there is a need in the art for improved methods of making III-nitride layers using ELO with a wide period for the opening areas. Specifically, there is a need for such a method where the device is grown with very low defect density and/or does not contain a coalescence region. To realize these needs, the present invention uses high-speed lateral growth under low V/III ratio growth conditions.

### SUMMARY OF THE INVENTION

To overcome the limitations in the prior art described above, and to overcome other limitations that will become apparent upon reading and understanding this specification, the present invention discloses a method for realizing high-speed lateral growth of III-nitride layers (as compared to low-speed vertical growth) using the ELO technique and utilizing the ELO technique for fabricating devices.

Previous attempts have been made to obtain growth conditions for high-speed lateral growth of III-nitride layers using the ELO technique. In this invention, it has been found that a low V/III ratio, e.g., < 500, can result in high-speed lateral growth of III-nitride layers using the ELO technique.

However, it has also been found that there is a trade-off relationship between impurity concentrations in the III-nitride ELO layers and the speed of the lateral growth. Lateral growth at a higher speed will result in higher concentrations of impurities in the ELO layers, e.g., over 1 × 10¹⁸ cm⁻³. Specifically, in the low V/III ratio, the length of migration of Gallium (Ga) adatoms on a Gallium Nitride (GaN) layer is longer than in the usual growth conditions. This helps growth of an edge part of the ELO layer, and leads to an increase in the speed of the lateral growth.

However, the Ga adatoms on the GaN layer are more likely to bond with the impurities, such as Carbon (C), Oxygen (O), Silicon (Si), etc., due to the lack of chances to bond to Nitrogen (N) atoms. The existence of the high impurity doping layer causes absorption and scattering of light generated in an active region, which leads to deterioration of device characteristics. Hereafter, the high impurity doping layer made by the ELO technique is called a coloring layer, because the layer is brown in color due to the high impurity doping.

The high-speed lateral growth has several advantages for devices and a device fabrication, including the following:
1. The high-speed lateral growth is important in reducing the cost of devices, because of the decrease in growth time in a metal-organic chemical vapor deposition (MOVCD) reactor, and the decrease in the amount of waste of the metal-organic source.
2. The high-speed lateral growth has the effect of suppressing the speed of vertical growth. The aspect ratio of the ELO layer between the width and height of the layer can be reduced, which allows for thin devices. Thin devices are preferable for micro-sized light-emitting diodes (micro-LEDs or µLEDs) and vertical cavity surface emitting lasers (VCSELs). For example, in the micro-LED case, the thin device can decrease the amount of the light from side facets of the device due to a reduction in the area of the side facet. The suppression of the light extraction from the side facet of the device can reduce crosstalk between adjacent devices, such as micro-LEDs used in displays. In the VCSEL case, thin devices can have a short cavity length, which leads to a higher gain device.
3. In the slow-speed lateral growth case, there may be high-speed vertical growth, which sometimes enhances fluctuations in the height among the ELO layers. Such fluctuations are not desired when bonding the ELO layers for the sake of removing the ELO layers from the substrate. Suppressing the fluctuations in the height of the ELO layers by increasing lateral growth is important to obtain a high yield when bonding these layers. Moreover, the higher the height of the ELO layer, the slower the speed of lateral growth, because the lateral growth needs more supply of materials. Thus, the height of the ELO layer should be as low as possible.
4. To obtain a large size chip that does not contain the coalescence region, the period of the growth restrict mask is set as wide as possible. For example, when the width of the period of the growth restrict mask is 20 µm - 30 µm, it becomes very difficult to cover the growth restrict mask with the ELO layer due to the slow-speed lateral growth. In this invention, the high-speed lateral growth can cover the width of the growth restrict mask with the ELO layer, even when the width of the period of the growth restrict mask is over 50 µm.

To gain these advantages, this invention can eliminate the trade-off relationship above.

This invention proposes a method to grow and fabricate many different types of devices, such as LEDs, micro-LEDs, VCSELs, laser diodes (LDs), photodetectors (PDs), and power devices, by utilizing a high-speed lateral growth and avoiding light absorption from an active region. Specifically, the present invention eliminates a coloring layer from the device, and removes devices from the substrate, in an easy, fast, and high-yield manner.

### BRIEF DESCRIPTION OF THE DRAWINGS

Referring now to the drawings in which like reference numbers represent corresponding parts throughout:

FIGS. 1a 1b 1c 1d 1e 1f 1g 1h 1i 1j 1k 1l 1m 1n 1o 1p are schematics of device structures fabricated according to the present invention.

FIGS. 2a 2b 2c 2d 2e 2f 2g 2h 2i 2j 2k 2l 2m 2n 2o 2p 2q) are schematics of device structures fabricated according to the present invention, which are variants of the schematics of FIGS. 1a 1b 1c 1d 1e 1f 1g 1h 1i 1j 1k 1l 1m 1n 1o 1p.

FIGS. 3a 3b 3c 3d 3e 3f 3g are schematics of device structures fabricated according to the present invention, which are variants of the schematics of FIGS. 1a-1p 2a-2q.

FIGS. 4a 4b 4c are schematics of device structures fabricated according to the present invention, which are variants of the schematics of FIGS. 1a-1p 2a-2q 3a-3g

FIG. 5 is a scanning electron microscope (SEM) image showing cracks that occur without voids when a growth restrict mask is buried by device layers.

FIG. 6 is a graph of Secondary Ion Mass Spectrometry (SIMS) profiling data for a coloring layer showing the C, O, Si concentration (atoms/cm³) vs. depth (µm).

FIG. 7 is a schematic of a growth restrict mask.

FIGS. 8a 8b 8c) are SEM images of a growth restrict mask, III-nitride ELO layer, coloring layer and flattening layer.

FIGS. 9a 9b are schematics of device packaging fabricated according to the present invention.

FIG. 10 is a flowchart that illustrates a method for removing devices from a substrate using an ELO technique.

### DETAILED DESCRIPTION OF THE INVENTION

In the following description of the preferred embodiment, reference is made to a specific embodiment in which the invention may be practiced. It is to be understood that other embodiments may be utilized and structural changes may be made without departing from the scope of the present invention.

### Overview

The following describes the methods proposed by this invention.

### Method 1

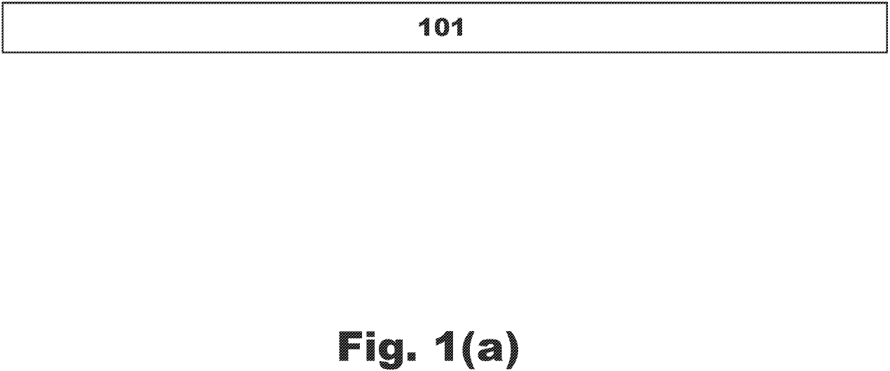

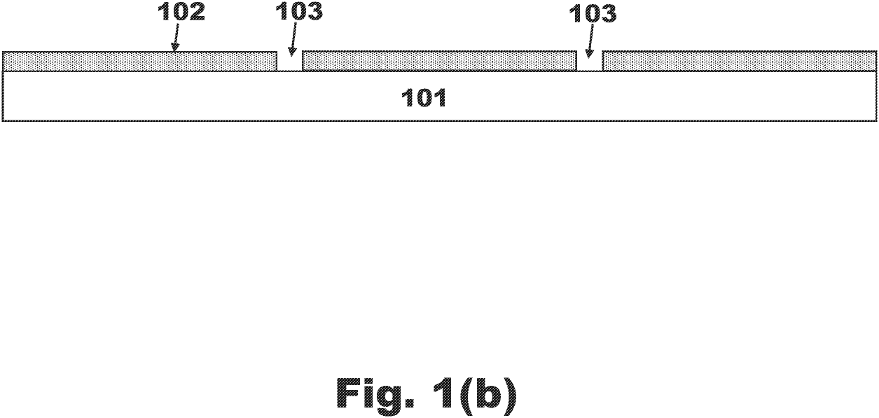

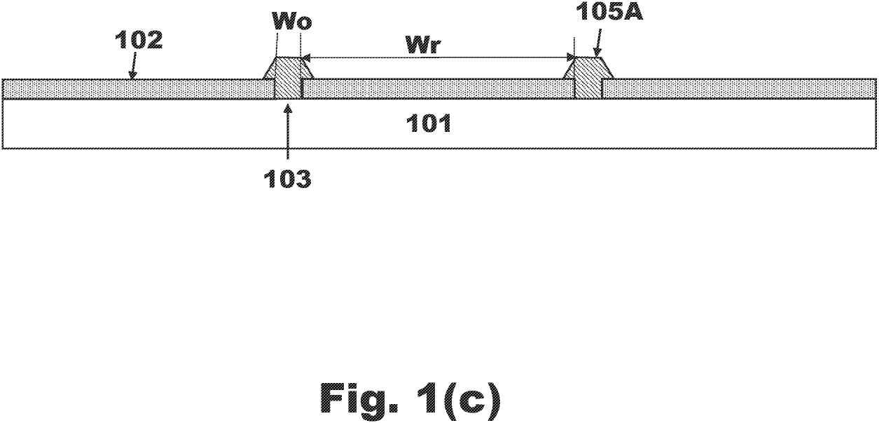

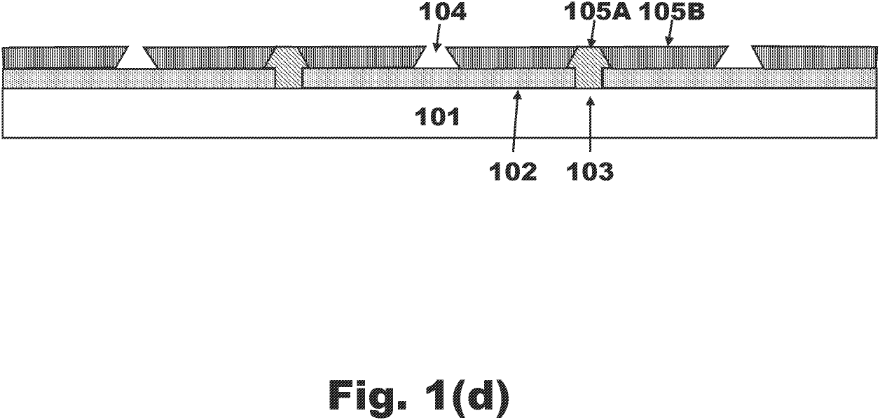

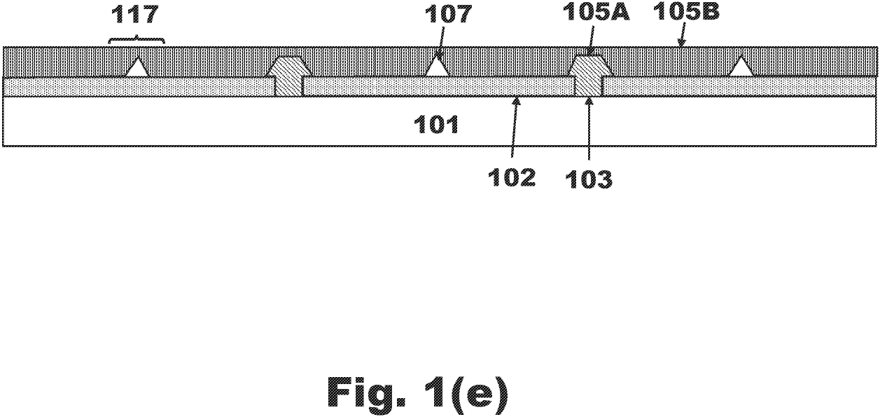

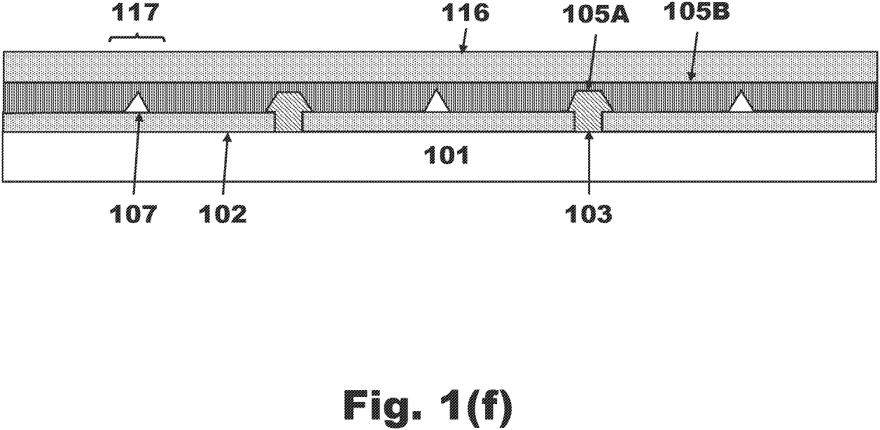

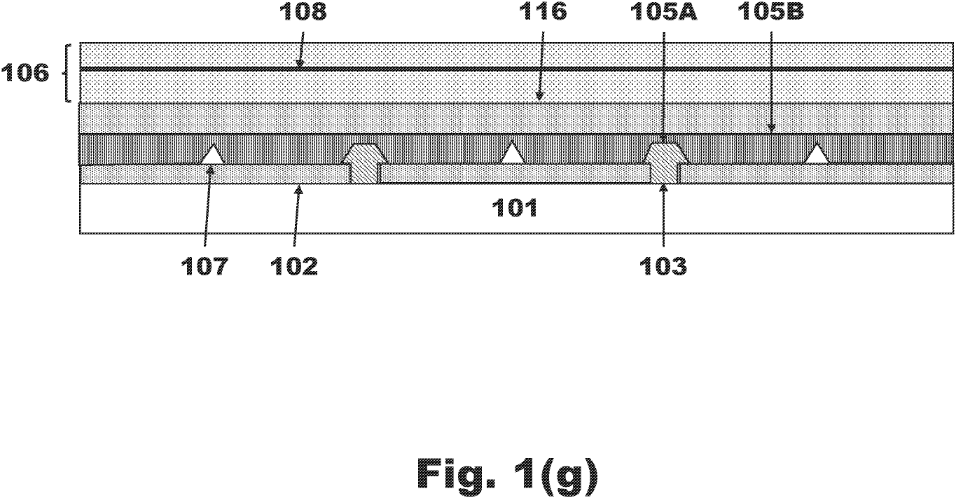

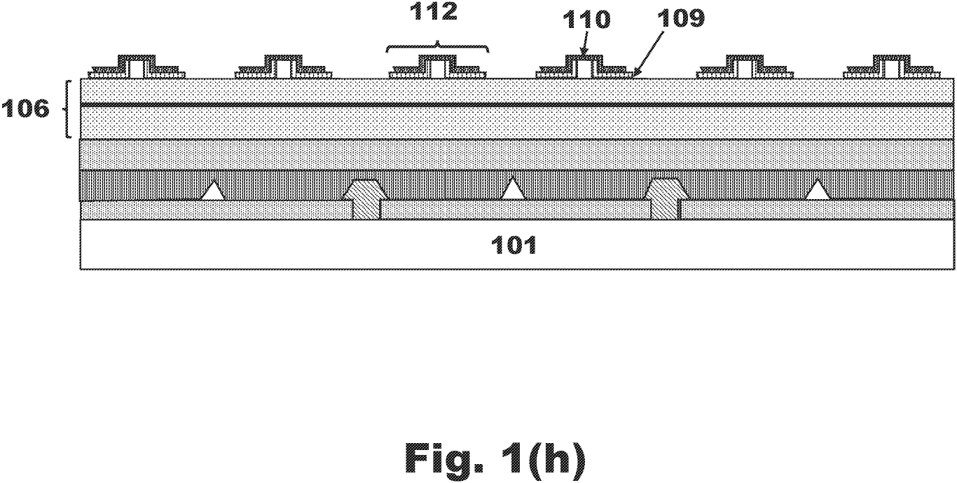

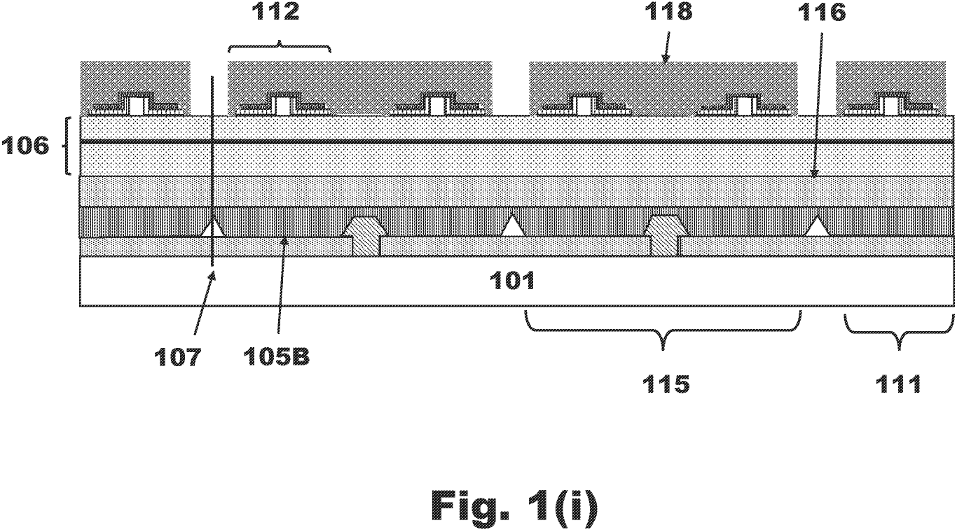

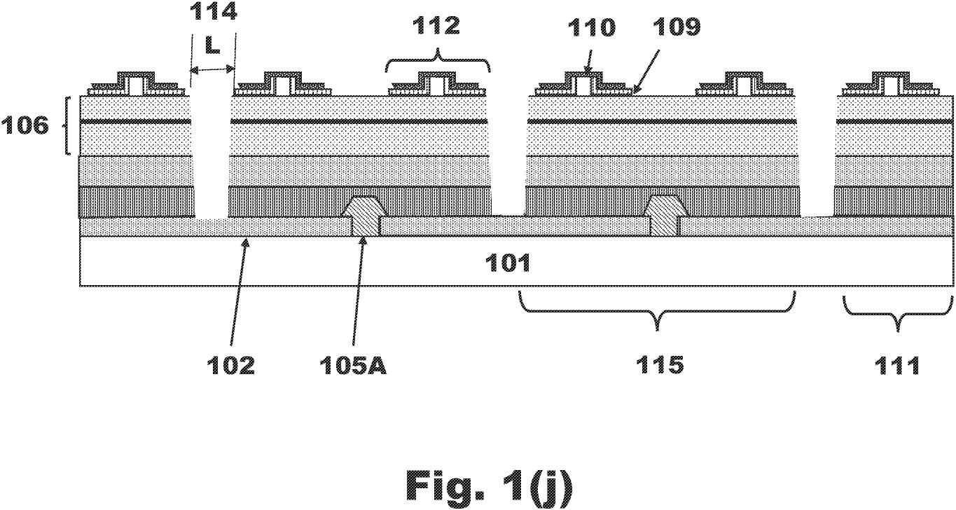

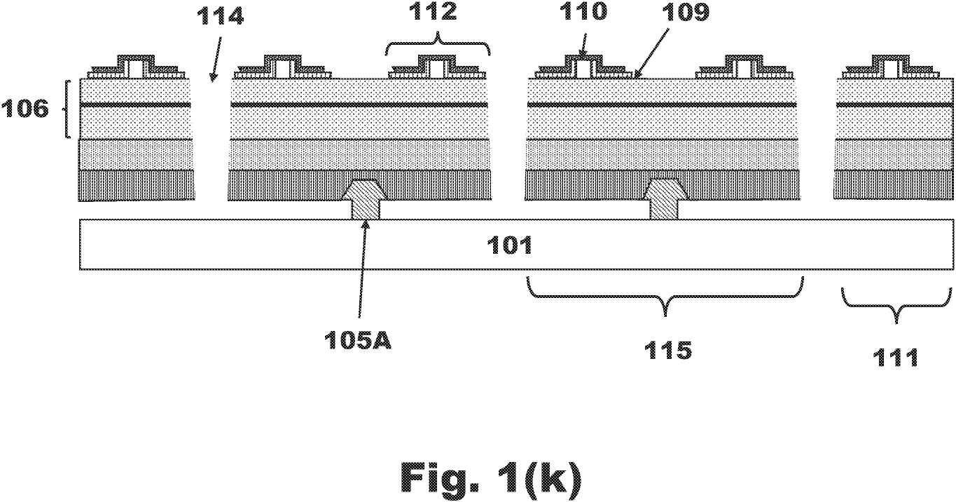

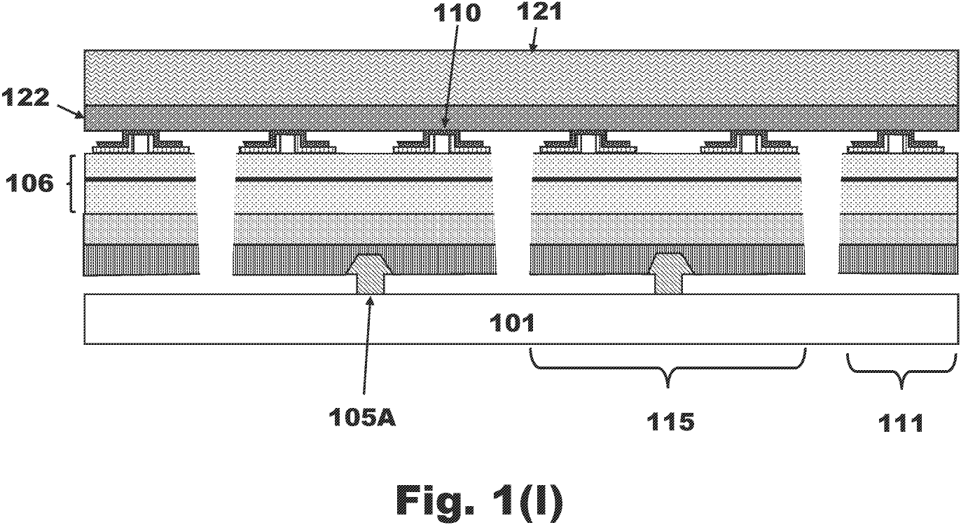

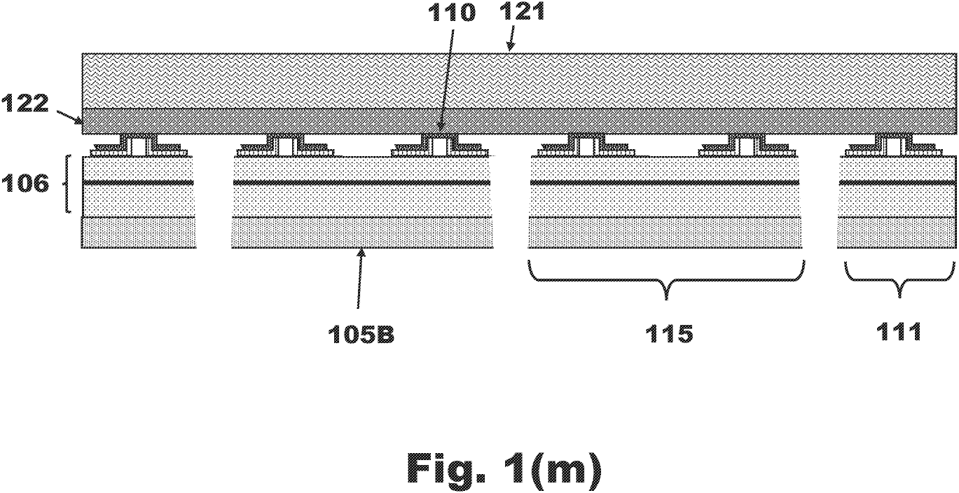

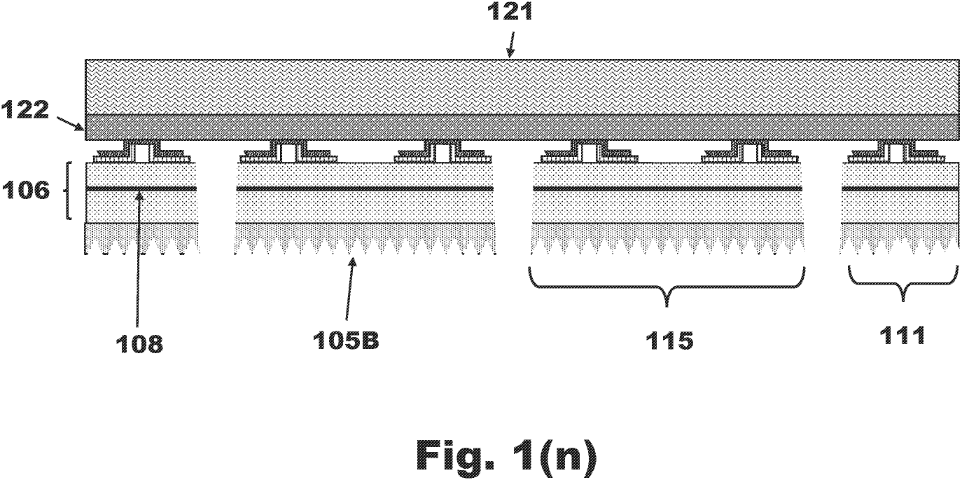

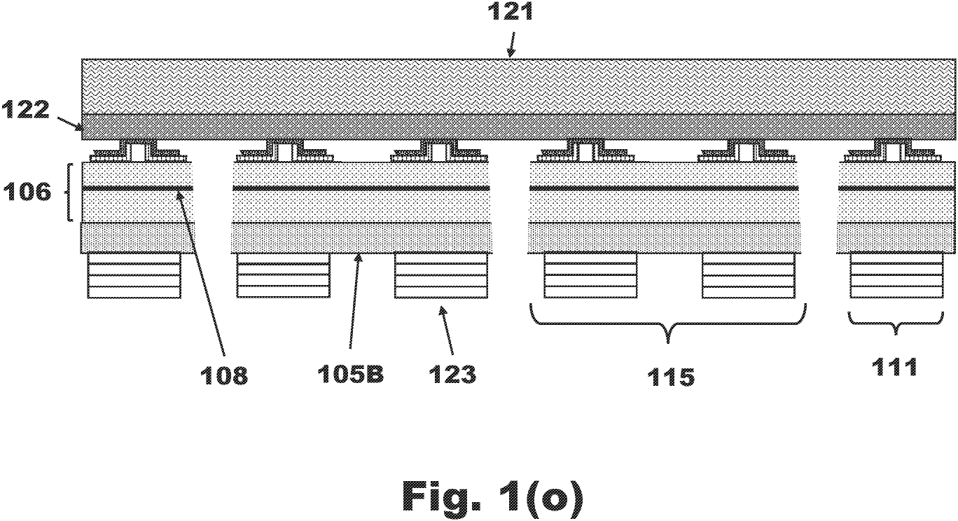

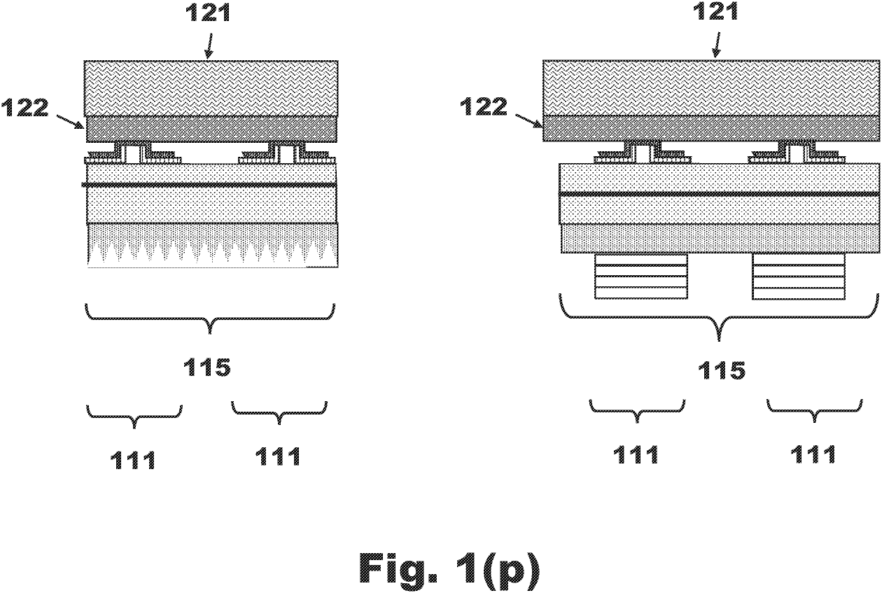

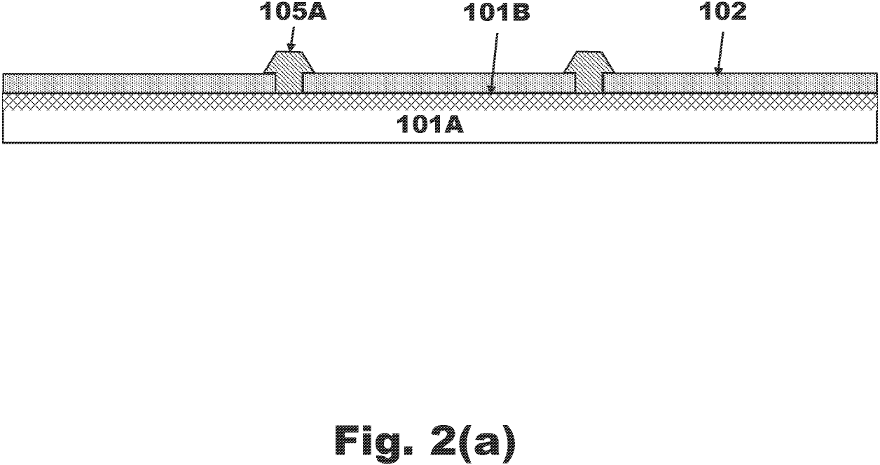

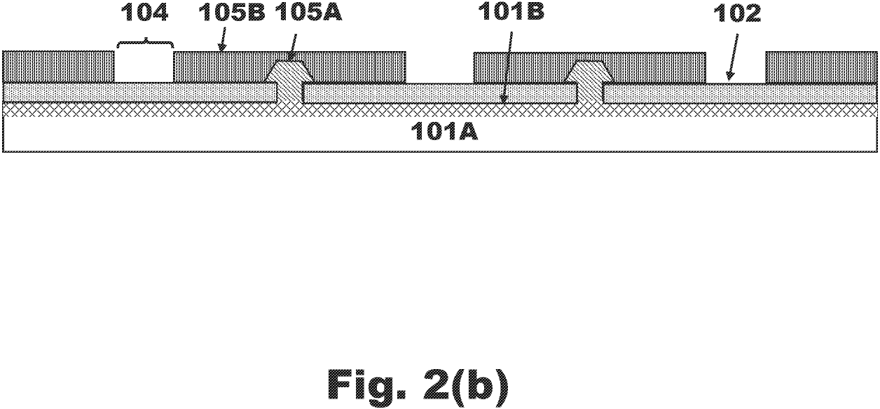

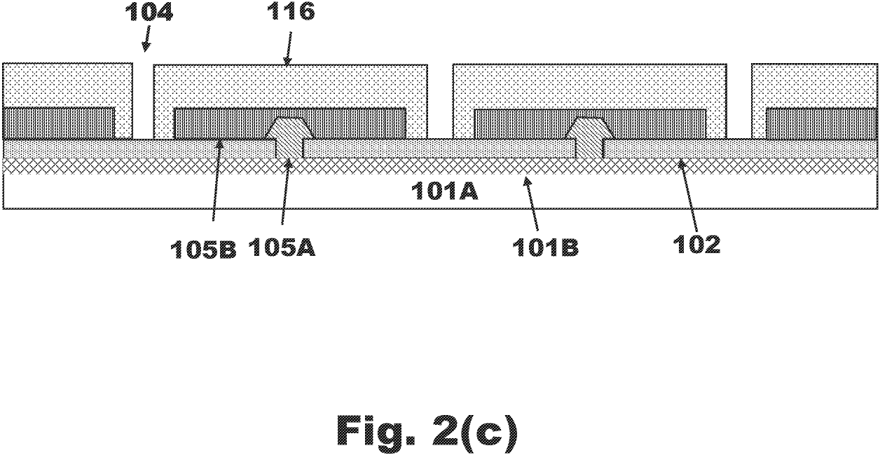

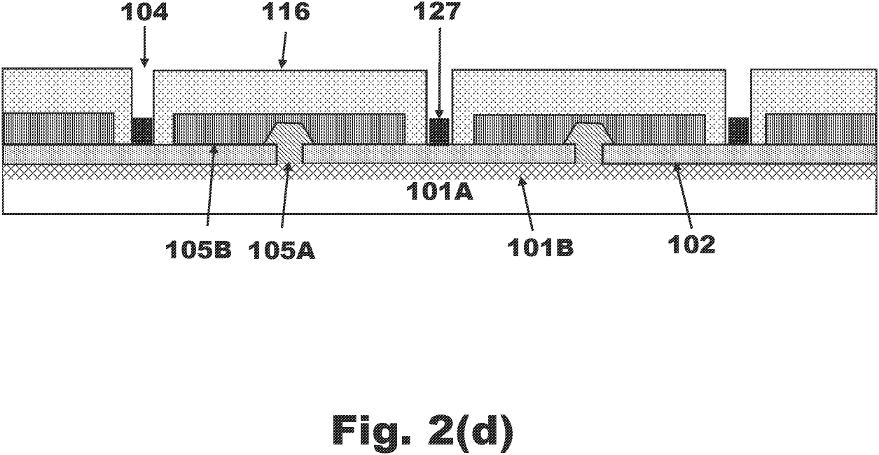

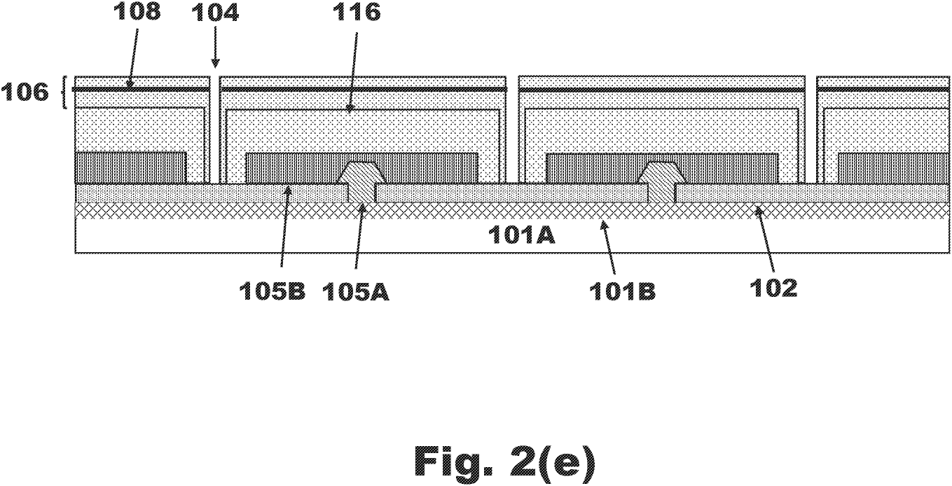

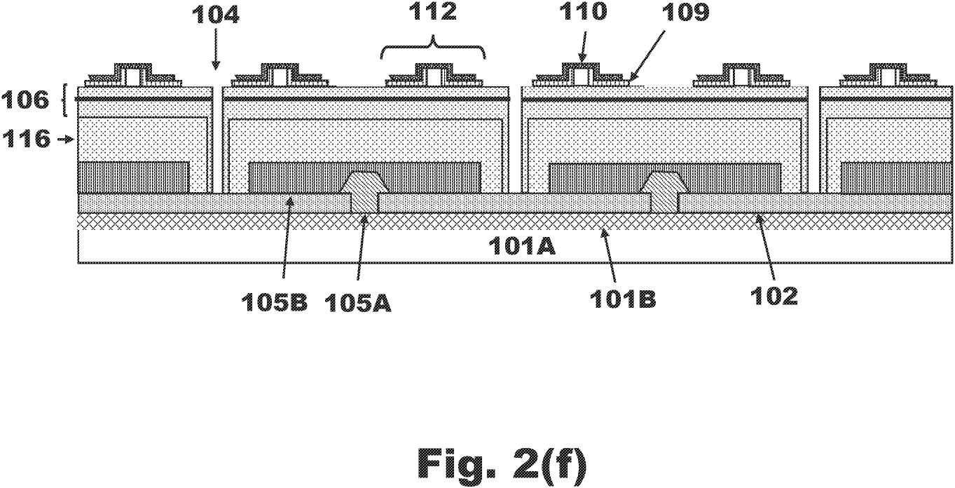

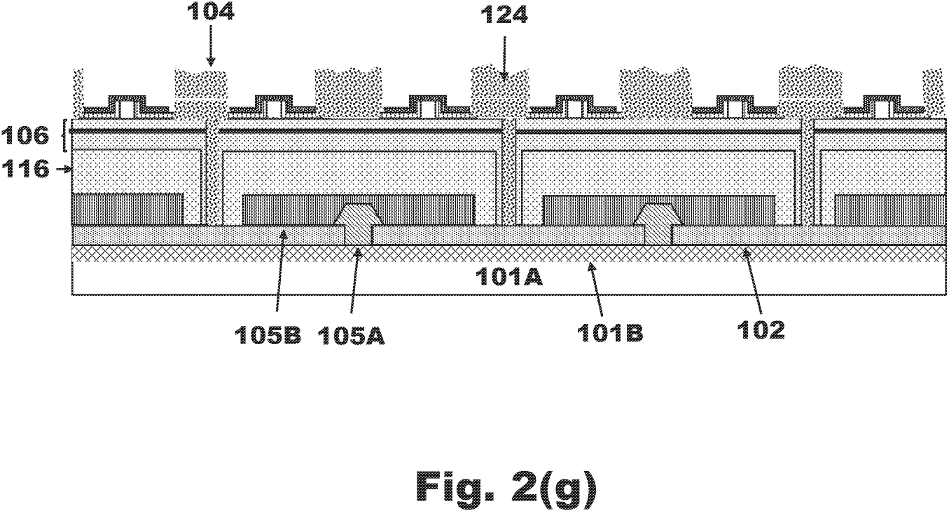

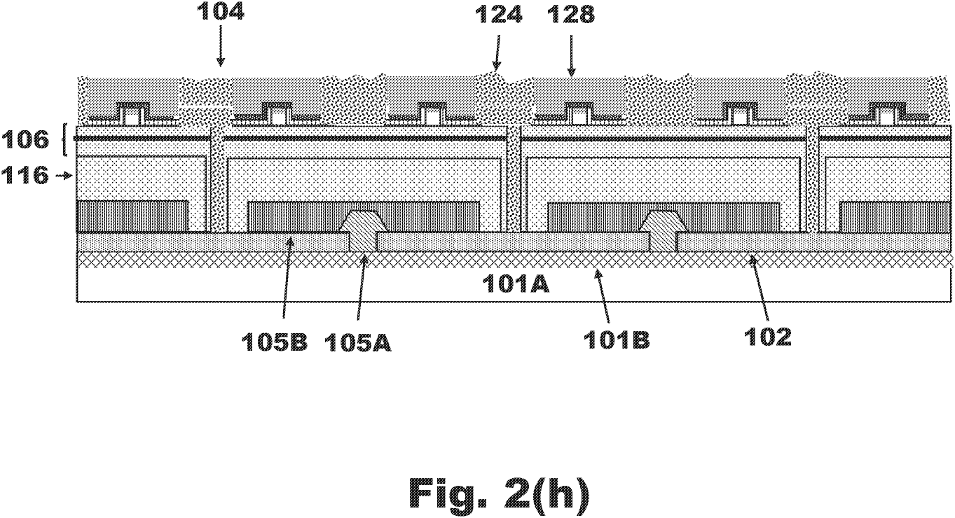

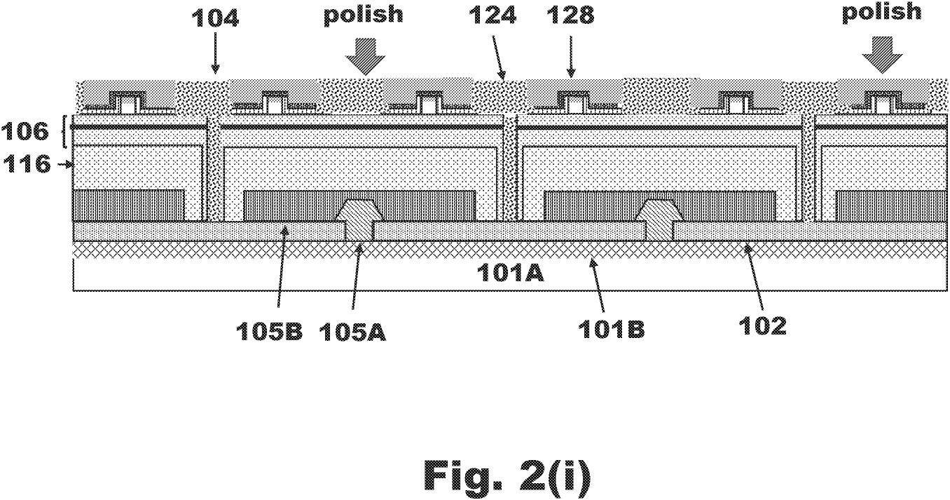

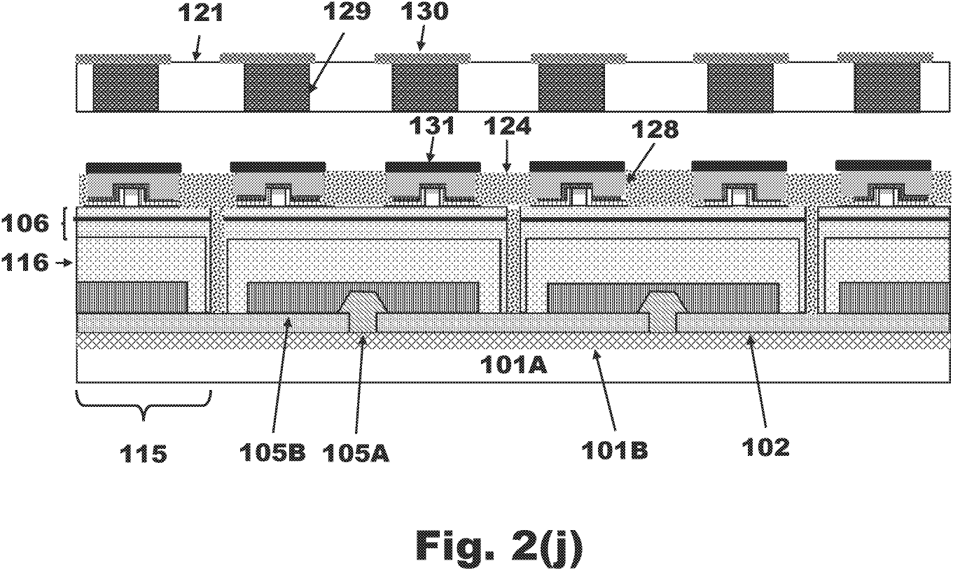

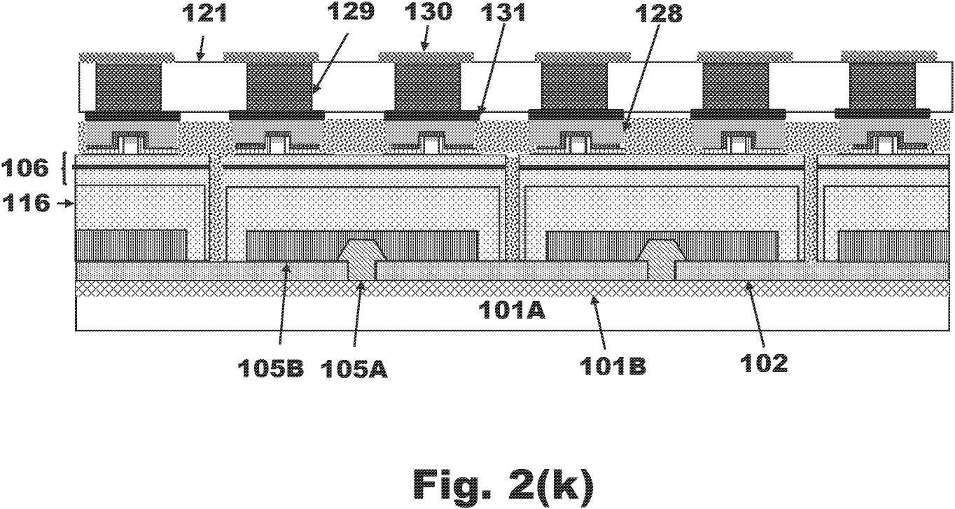

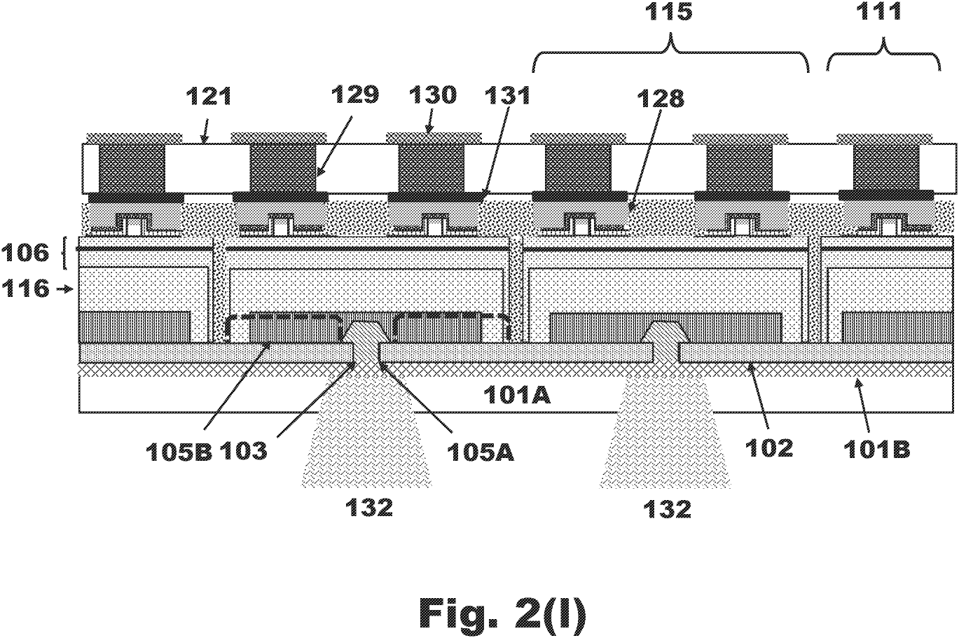

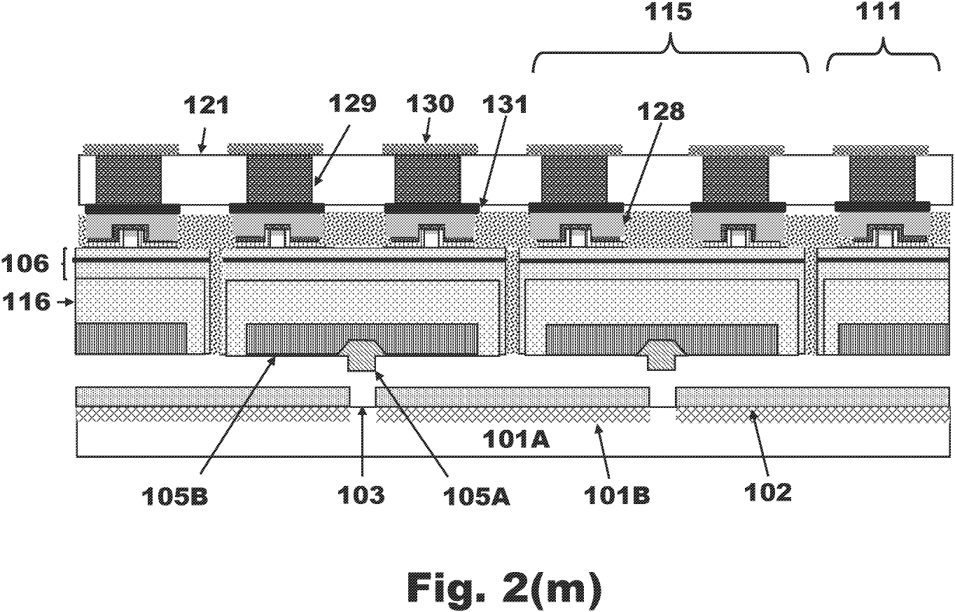

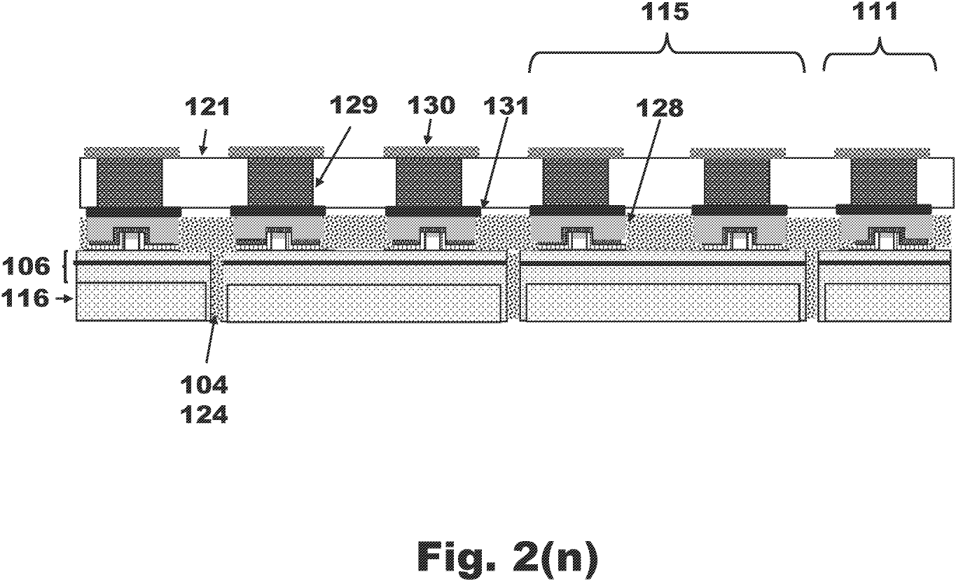

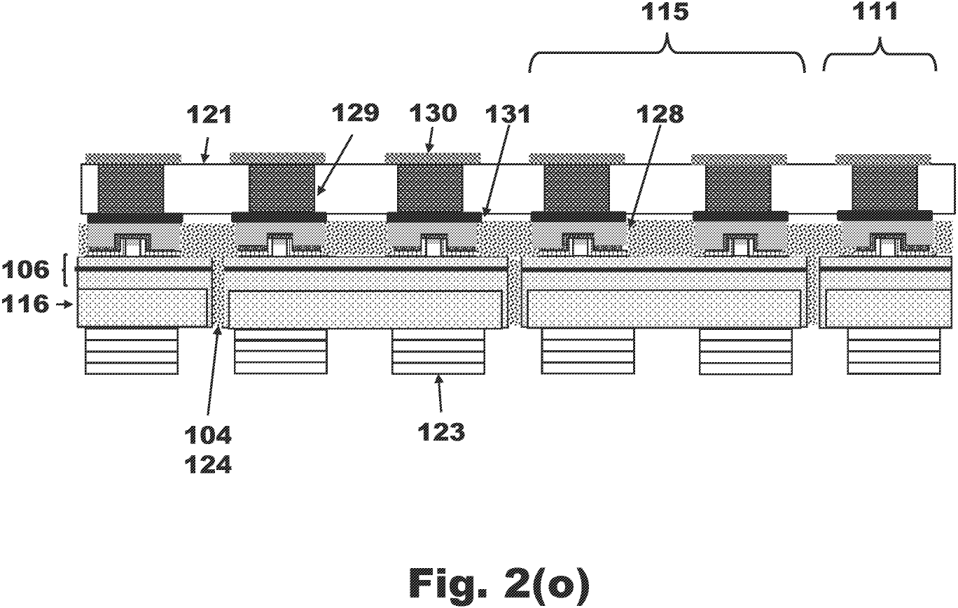

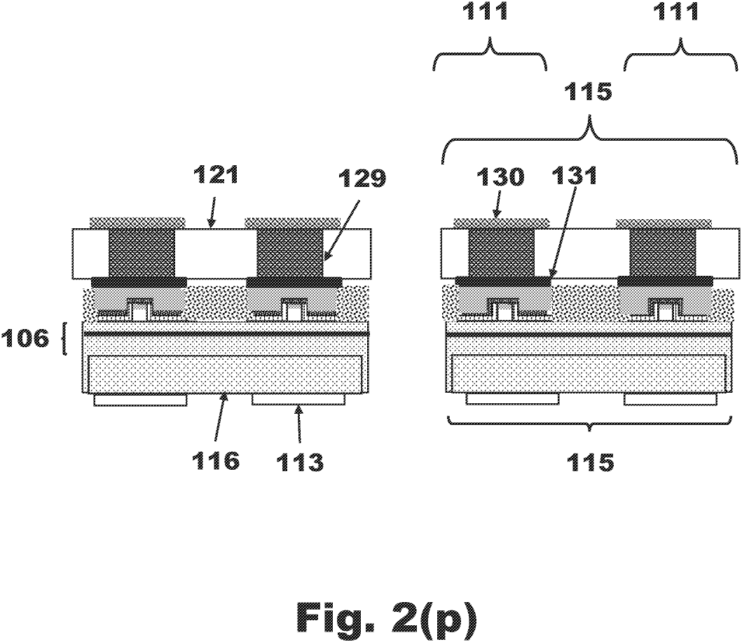

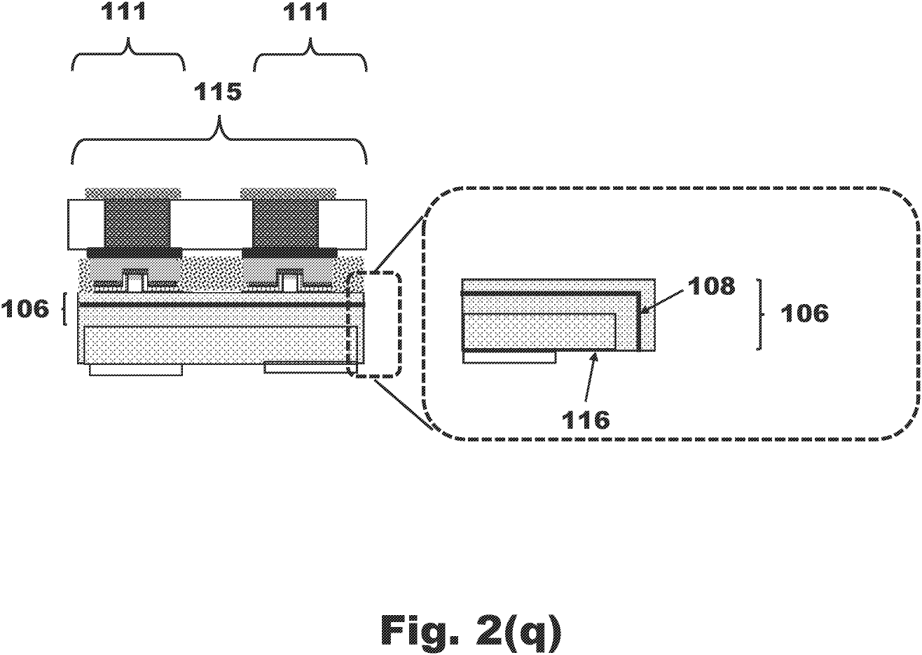

This method comprises the steps of:
1. Grow a coloring layer:
   1-1. on a GaN substrate, as shown in FIGS. 1a-1p, or
   1-2. on a foreign or hetero-substrate, as shown in FIGS. 2a-2q.
2. Grow III-nitride device layers on the coloring layer.
3. Remove a bar of the device layers including the coloring layer:
   3-1. after coalescing the coloring layer, as shown in FIGS. 1a-1p, and
      3-1-1. using a hooking layer method, or
   3-2. without coalescing the coloring layer, as shown in FIGS. 2a-2q).
4. Eliminate the coloring layer from the bar of the device by polishing, dry-etching or wet etching, as shown in FIGS. 1a-1p, FIGS. 2a-2q and FIGS. 3a-3g

In this method, the bar including the coloring layer made by the ELO technique is removed from the substrate, which may be a III-nitride substrate, such as a GaN substrate, or a hetero-substrate, such as a sapphire, silicon, silicon carbide or other substrate. Removing the bar from the substrate can reveal the coloring layer on the back side of the bar. After that, the coloring layer is removed by polishing or dry or wet etching methods. By doing this, the adverse effects of the coloring layer can be eliminated and various advantages can be obtained from the high-speed growth in the lateral direction.

### Method 2

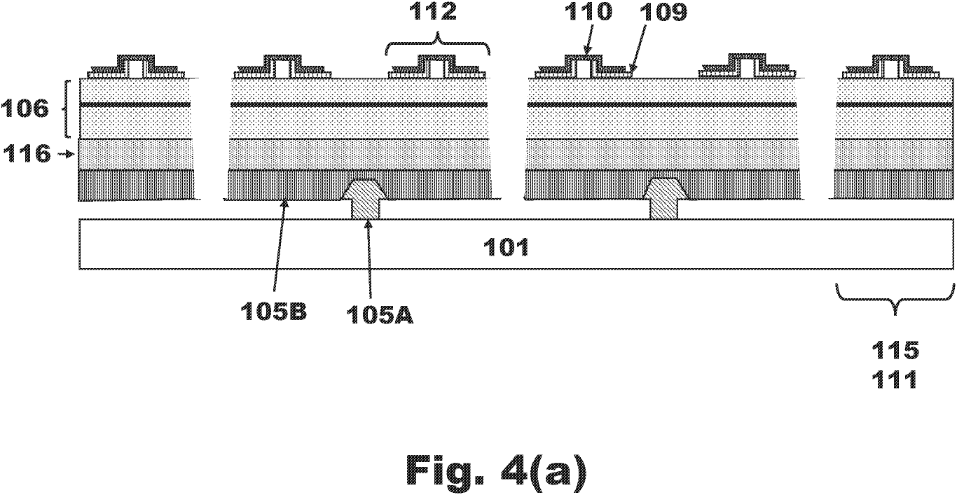

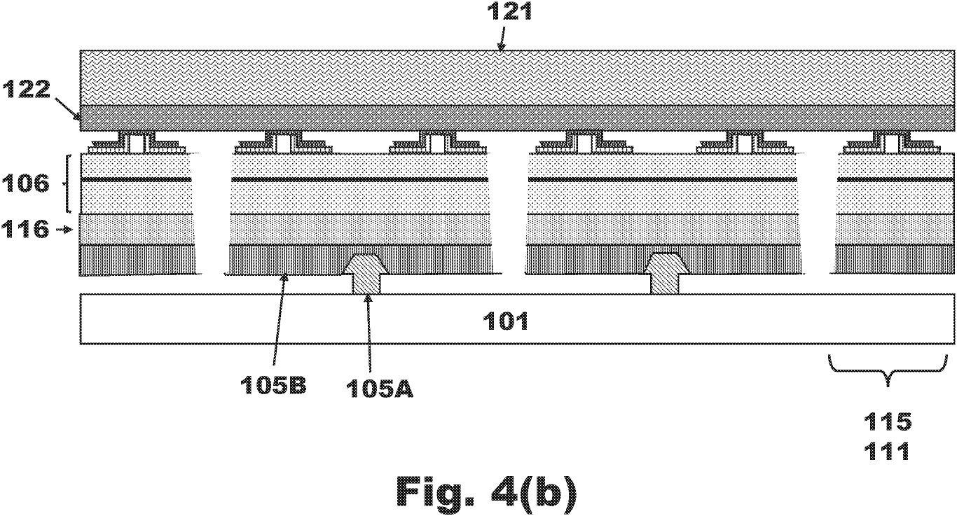

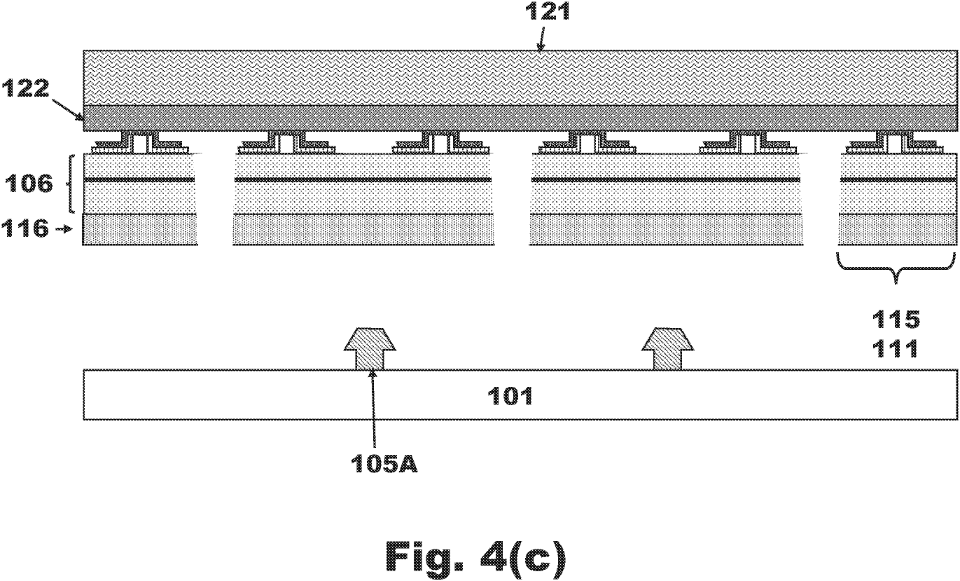

This method comprises the steps of:
1. Grow the coloring layer (with or without coalescence).
2. Grow the III-nitride device layer on the coloring layer.
3. Eliminate the coloring layer by wet etching and remove the bar including the coloring layer at the same time, as shown in FIGS. 4a-4c.

This method provides another option for removing the coloring layer. The coloring layer can be removed by wet etching before removing the bar from the substrate. Dissolving the growth restrict mask can reveal the back side of the coloring layer and form a void under the coloring layer. The coloring layer can be dissolved by wet etching using an etchant such as Tetramethylammonium hydroxide (TMAH), Potassium hydroxide (KOH), Sodium hydroxide (NaOH), and so on. After that, the bar can be removed from the substrate.

It is also possible to separate the bar by etching, wherein controlling the etching time can dissolve the coloring layer at an upper part of the opening area. This can make the bar separate from the substrate. Consequently, the substrate is removed and the coloring layer is etched simultaneously. Since the coloring layer contains a large amount of impurities, it is easy to dissolve as compared to a normal layer.

### Both Methods

Moreover, in both methods, a wet or dry etching method can etch from the back side of the coloring layer. If these techniques are used with a c-plane polar III-nitride substrate, the back surface of the coloring layer is Nitrogen (N) polar, which is easier to dissolve and etch than an opposite front surface, which is Gallium (Ga) polar.

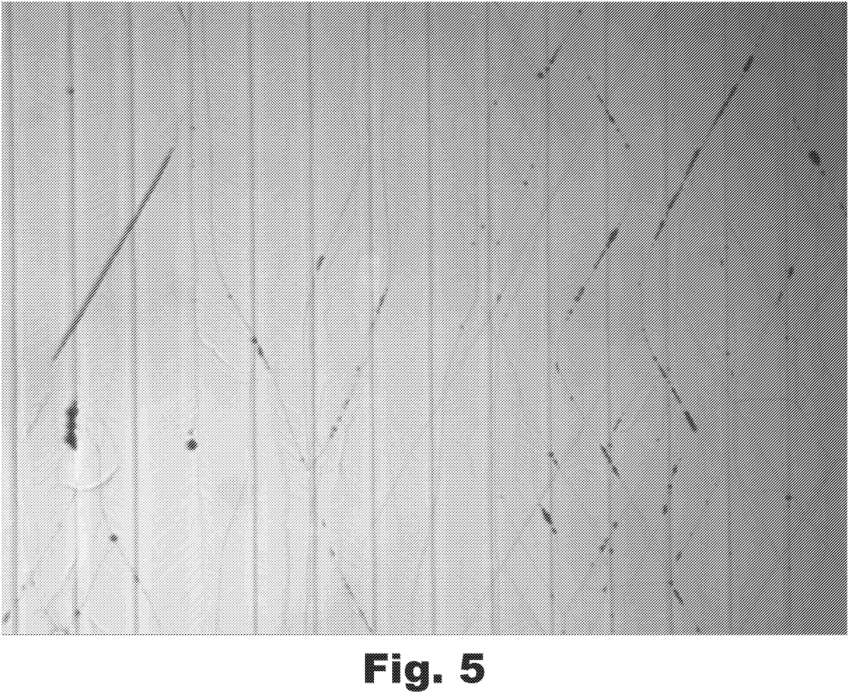

Both methods also provide the following advantages:
1. The coloring layer contains a large amount of impurities. The layer made by the low V/III ratio growth condition is likely to incorporate Carbon, which is originated from the Ga source, such as Triethylgallium (TEG) or Trimethylgallium (TMG). Carbon plays a role in scattering and absorption losses of light from the active region. If the device contains the coloring layer, there is likely a large loss. In this invention, removing the bar makes it easier to eliminate the coloring layer. This invention allows the use of a polishing method, dry etching method or wet etching method. The present invention eliminates the coloring layer and separates the bar from the substrate at the same time. This invention can be used to form very thin devices due to the high-speed lateral growth, which can suppress a vertical growth rate. In one embodiment, the devices have a thickness of less than 20 µm; it is also possible to make devices with a thickness under 10 µm. This invention is especially useful for micro-LEDs, because it can suppress cross-talk effects between adjacent micro-LEDs due to the reduction of the amount of the light extraction through side facets of the device. This invention is also useful for VCSELs, because it can be used to make a short cavity for the VCSEL. The VCSEL can also have a high gain due to the reduction in internal losses of the cavity.
2. The coloring layer can form voids in the III-nitride layer, even with coalescence between adjacent ELO layers. The growth conditions of the coloring layer results in changes to the angle of the edge of the coloring layer, which makes it possible to form the voids. The voids prevent cracks from occurring in the III-nitride device layers, by reducing internal stress. In many cases without voids, cracks occur when the growth restrict mask is buried by the device layers, due to the difference of the thermal expansion co-efficiency between the growth restrict mask and the device layers, as shown in FIG. 5. The void under the device layer can release the stress. In this case, the voids are placed directly on the growth restrict mask and are formed in a large manner. In the case where there is no coalescence of the ELO layers, the gap between adjacent ELO layers can also release the stress. This helps avoid cracks from occurring.
3. In the case where the backside of the bar is polished to eliminate the coloring layer, chemical-mechanical polishing (CMP) can be used, which makes the polished surface very flat, for example, with a surface roughness less than several nanometers (nm). As a result, distributed Bragg reflectors (DBRs) for VCSELs can be placed on the polished surface.
4. The present invention can prevent and alleviate compensation of p-type layer by the growth restrict mask decomposing. Generally, in the ELO technique, the growth restrict mask may be comprised of Silicon dioxide (SiO₂), Silicon nitride (SiN), and the like. However, both Silicon and Oxygen atoms are n-type dopants for GaN. Thus, if the growth restrict mask decomposes during the growth of p-type layer, these atoms compensate the p-type dopant in the p-type layer. The high-speed lateral growth can cover the growth restrict mask faster. When the device layers are grown, most of the growth restrict mask has been covered with the III-nitride ELO layer. This can prevent the decomposition of the growth restrict mask, which can avoid the compensation of p-type layer. The present invention can use either a III-nitride substrate or a hetero-substrate, such as Sapphire, Silicon carbide (SiC), Lithium aluminate (LiAlO₂), Si, etc., as long as it enables growth of a III-nitride-based semiconductor layer through a growth restrict mask. In the case using a III-nitride substrate, the present invention can obtain high quality III-nitride-based semiconductor layers and avoid bowing or curvature of the substrate during epitaxial growth due to homo-epitaxial growth. As a result, in case of using a III-nitride substrate can also easily obtain devices with reduced defect density, such as dislocation and stacking faults.

### Identification of Elements

The figures identify a number of different labeled elements, including the following:
III-nitride substrate 101,
hetero-substrate 101A,
III-nitride template or underlayer 101B,
growth restrict mask 102,
opening area 103,
no-growth region 104,
initial growth layer 105A,
coloring layer 105B,
III-nitride semiconductor device layers 106,
void or void region 107,
active region 108,
current blocking layer 109,
p-type electrode 110,
device 111,
ridge structure 112,
n-electrode 113,
etching region 114,
bar 115,
flattening layer 116,
depressed portion 117,
photoresist 118,
hooking layer 119,
breaking point 120,
supporting plate 121,
solder 122,
distributed Bragg reflector (DBR) 123,
photoresist 124,
package 125,
heat sink 126,
cover layer 127,
copper layer 128,
vias 129,
pad electrode 130,
bonding metal 131, and
laser 132.

These elements are described in more detail below.

### Definitions of Terms

### Iiinitride-Based Substrate

The III-nitride-based substrate 101 is shown in FIG. 1a.

Any III-nitride-based substrate 101 that enables growth of a III-nitride-based semiconductor layer through a growth restrict mask 102 may be used, including any GaN substrate 101 that is sliced on a {0001}, {11-22}, {1-100}, {20-21}, {20-2-1}, {10-11}, {10-1-1}, {11-22}, {11-2-2} plane, etc., or other plane, from a bulk GaN crystal, as well as any Aluminum Nitride (AlN) substrate 101.

### Hetero-Substrate

Moreover, the present invention can also use a foreign or hetero-substrate 101A, as shown in FIG. 2a. For example, a Sapphire, Si, SiC, Gallium Arsenide (GaAs), etc., substrate 101A may be used in the present invention.

A III-nitride template or underlayer 101B, or other III-nitride, such as a GaN template or underlayer 101B, may be grown on a hetero-substrate 101A. The GaN template 101B is typically grown on the hetero-substrate 101A to a thickness of about 0.5 - 6 µm, and then the growth restrict mask 102 is disposed on the GaN template 101B or other III-nitride-based semiconductor layer 101B.

The growth restrict mask 102 may also be formed directly on the hetero-substrate 101A, and the initial growth layer 105A, which is a III-nitride ELO layer, may be grown directly on the growth restrict mask 102. In this instance, it is not necessary for the substrate 101A to have a III-nitride template or underlayer 101B.

### Growth Restrict Mask

The growth restrict mask 102 is shown in FIG. 1b and FIG. 2a.

The growth restrict mask 102 comprises a dielectric layer, such as SiO₂, SiN, SiON, Al₂O₃, AlN, AlON, MgF, ZrO₂, etc., or a refractory metal or precious metal, such as W, Mo, Ta, Nb, Rh, Ir, Ru, Os, Pt, etc. The growth restrict mask 102 may be a laminate structure selected from the above materials. It may also be a multiple-stacking layer structure chosen from the above materials.

The growth restrict mask 102 is deposited by sputter, electron beam evaporation, plasma-enhanced chemical vaper deposition (PECVD), ion beam deposition (IBD), etc., but is not limited to those methods.

The thickness of the growth restrict mask 102 is about 0.05 - 3 µm. The width of the stripes of the growth restrict mask 102 is preferably larger than 20 µm, and more preferably, the width is larger than 40 µm. The length of opening areas 103 in the growth restrict mask 102 is, for example, 200 to 35000 µm; and the width of the opening areas 103 in the growth restrict mask 102 is, for example, 2 to 180 µm.

ELO layers are grown from the opening areas 103 of the growth restrict mask 102, extending over the stripes of the growth restrict mask 102, and may or may not coalesce on the growth restrict mask 102. When the ELO layers do not coalesce on the growth restrict mask 102, this results in no-growth regions 104.

In one embodiment, the growth restrict mask 102 is formed with a 1 (µm-thick SiO₂ film, wherein the length of the opening areas 103 is 5000 µm; the width of the opening areas 103 is 3-10 µm; the intervals of the opening areas 103 are 50-150 µm; and the width of the stripes of the growth restrict mask 102 is 50-150 µm.

### Direction of the Growth Restrict Mask

On an c-plane free standing GaN substrate 101, the opening areas 103 of the growth restrict mask 102 are arranged in a first direction parallel to a 11-20 direction (a-axis) of the substrate 101 and a second direction parallel to a 1-100 direction (m-axis) of the substrate 101, periodically at a first interval and a second interval, respectively, and extend in the second direction.

On a c-plane GaN template 101B grown on a sapphire substrate 101A, the opening areas 103 are arranged in a first direction parallel to a 11-20 direction (a-axis) of the GaN template 101B and a second direction parallel to a 1-100 direction (m-axis) of the substrate 101A, periodically at a first interval and a second interval, respectively, and extend in the second direction.

On a m-plane free standing GaN substrate 101, the opening areas 103 are arranged in a first direction parallel to a 11-20 direction (a-axis) of the substrate 101 and a second direction parallel to a 0001 direction (c-axis) of the substrate 101, periodically at a first interval and a second interval, respectively, and extend in the second direction.

On a semipolar (20-21) or (20-2-1) GaN substrate 101, the opening areas 103 are arranged in a direction parallel to [-1014] and [10-14], respectively.

Alternatively, a hetero-substrate 101A can be used. When a c-plane GaN template 101B is grown on a c-plane sapphire substrate 101A, the opening area 103 is in the same direction as the c-plane free-standing GaN substrate 101; and when an m-plane GaN template 101B is grown on an m-plane sapphire substrate 101A, the opening area 103 is same direction as the m-plane free-standing GaN substrate 101. By doing this, an m-plane cleaving plane can be used for dividing bars of devices with the c-plane GaN template 101B, and a c-plane cleaving plane can be used for dividing bars of devices with the m-plane GaN template 101B, which is much preferable.

The width of the opening 103 is typically constant in the second direction, but may be changed in the second direction as necessary.

### III-Nitride-Based Semiconductor Layers

The initial growth layer 105A, the coloring layer 105B (which is also a III-nitride ELO layer), the III-nitride semiconductor device layers 106, and the flattening layer 116, are shown in FIGS. 1c-1g, and comprise III-nitride-based semiconductor layers. These layers 105A, 105B, 106 and 116, can include Ga, In, Al and/or B, along with N, as well as other impurities, such as Mg, Si, Zn, O, C, H, etc.

The III-nitride semiconductor device layers 106 generally comprise more than two layers, including at least one layer among an n-type layer, an undoped layer and a p-type layer. The III-nitride semiconductor device layers 106 specifically comprise a GaN layer, an AlGaN layer, an AlGaInN layer, an InGaN layer, etc.

### Coloring Layer

In this invention, the coloring layer 105B, which is also a III-nitride ELO layer, is grown on the growth restrict mask 102 with a very low V/III ratio growth condition. In one embodiment, the coloring layer 105B is brown in color. The color intensity depends on the impurity concentration. A very low V/III ratio growth condition enhances the chance to bond the Ga adatoms of the growth surface with other impurities, such as Carbon, Oxygen, Silicon, etc. Thus, the coloring layer 105B contains a large amount of impurities. Among the impurities in the coloring layer 105B, Carbon is the most problematic. Since Carbon is obtained from the Ga source, such as TEG or TMG, it is difficult to avoid containing Carbon into the layer 105B.

In the present invention, the definition of the coloring layer 105B has a Carbon concentration over 5×10¹⁷ cm⁻³. If a GaN layer is grown with usual growth conditions, such as a high V/III ratio growth condition (>3000), the concentration of Carbon is under 1×10¹⁶ cm⁻³. The growth condition being able to obtain the high-speed lateral growth results in the layer containing Carbon in a higher concentration than its usual condition, e.g., by one order of magnitude. This Carbon concentration is over 10¹⁹ cm⁻³ depending on the V/III condition. A higher Carbon concentration results in a higher speed in the lateral growth. Thus, there is a trade-off relationship. The high Carbon concentration in the layer also strongly absorbs light from an active region.

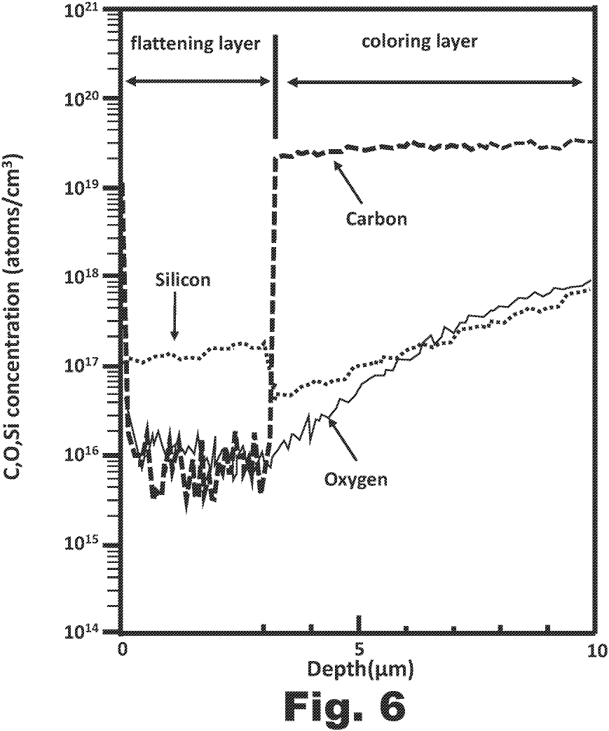

Herein, the coloring layer 105B is explained by the SIMS profiling data, as shown in FIG. 6. FIG. 6 is a graph of the SIMS depth profiling data in terms of impurities such as Carbon, Oxygen, Silicon, etc. The layers measured are comprised of two layers, which are the flattening layer 116 and the coloring layer 105B, from the surface in this order. The structure is the same as FIG. 1f. The flattening layer 116 grown with the high V/III condition (>3000) contains Carbon under a measurement limit. On the other hand, the coloring layer 105B contains Carbon over 10¹⁹ cm⁻³, since the coloring layer 105B is grown with a low V/III condition (< 500).

By doing this, the low Carbon concentration layer can grow on the coloring layer 105B. To reduce the light absorption, at least part of the coloring layer 105B should be removed, although it is much preferable to remove the entire coloring layer 105B.

### Semiconductor Device

The present invention discloses a method for the removal of one or more devices 111 formed on a substrate 101 using void regions 107 in the epilayers. The devices 111 may comprise light-emitting diodes (LEDs), laser diodes (LDs), photodetectors (PDs), Schottky barrier diodes (SBDs), metal-oxide-semiconductor field-effect-transistors (MOSFETs), or other opto-electronic devices.

This invention is particularly useful for micro-LEDs and laser diodes, such as edge-emitting lasers and vertical cavity surface-emitting lasers (VCSELs). This invention is especially useful for a semiconductor laser which has cleaved facets.

### The Area of Forming a Device

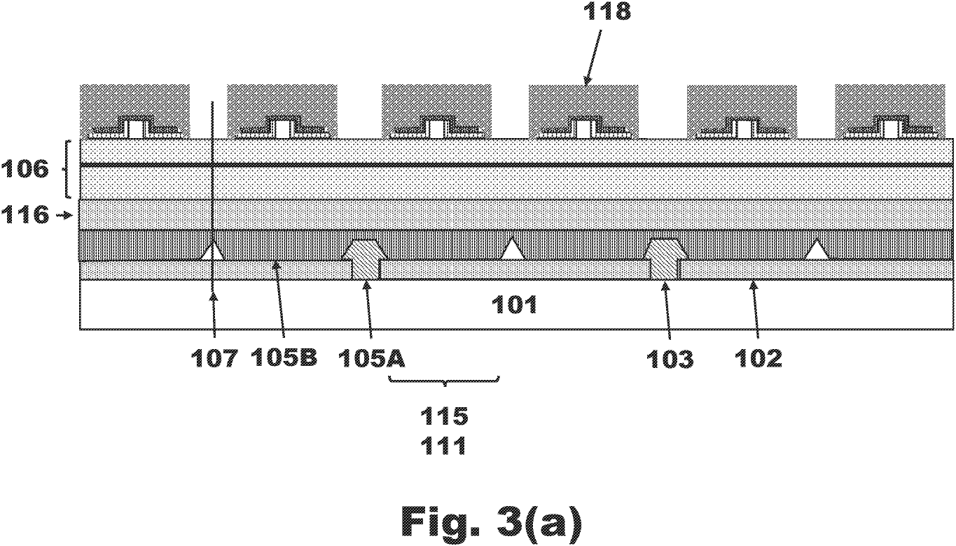

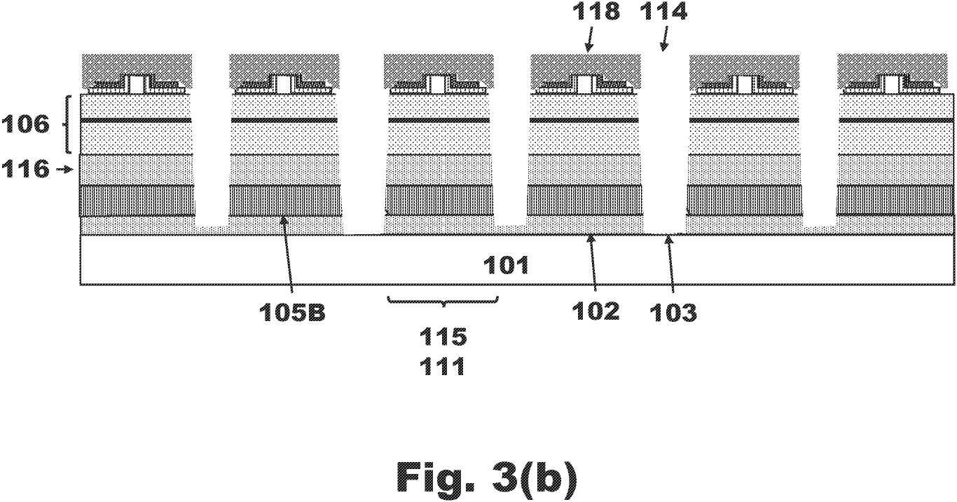

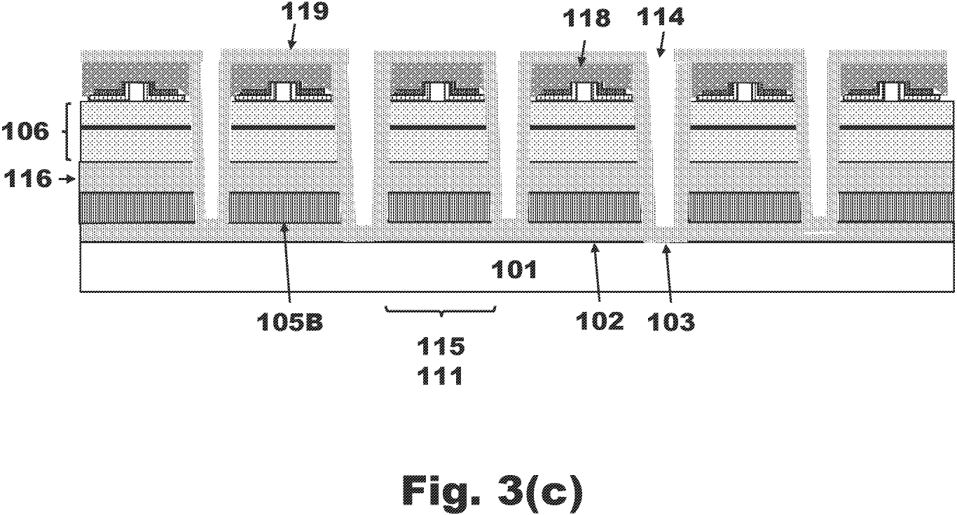

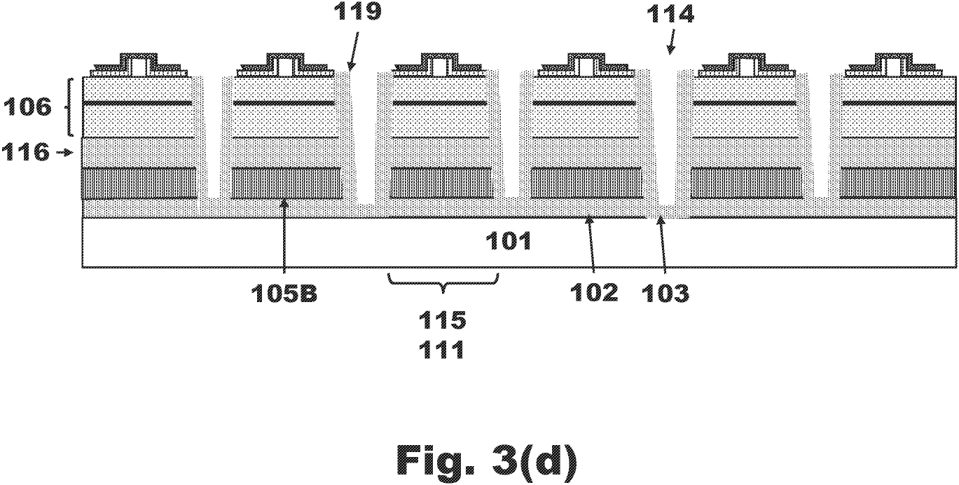

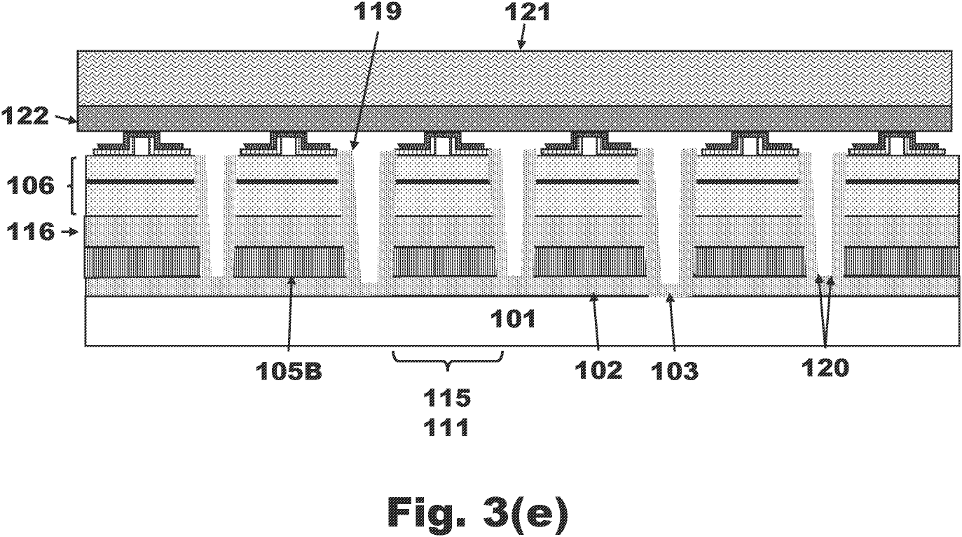

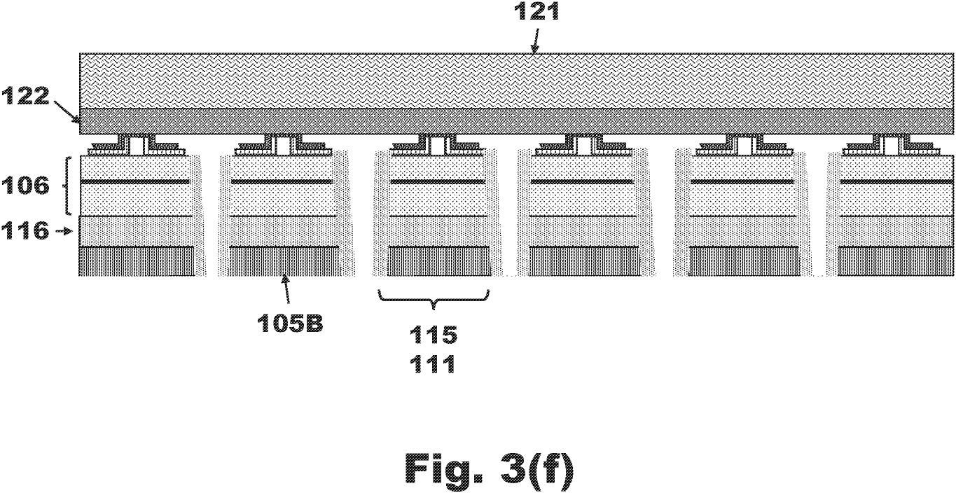

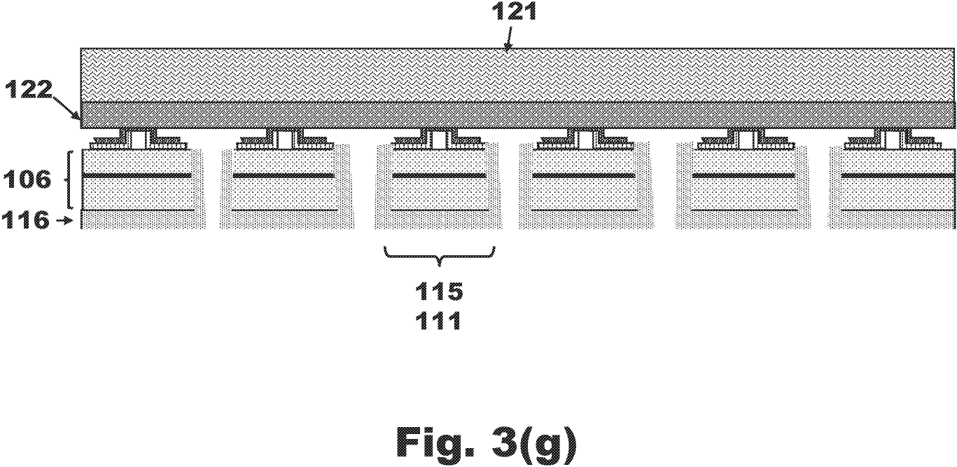

In the present invention, the area for forming a device 111 preferably avoids the center of the void region 107, as shown in FIG. 1i and FIG. 3a. This area includes a high density of dislocations, because the coalescence of the coloring layer 105B occurs at the center of the void region 107. It is much preferable that the device 111 be formed in an area about 5 µm away from the center of the void region 107. In the case of a laser diode device 111, the ridge structure 112 of the laser is preferably located in the same area.

### Supporting Plate

Once removed, a bar 115 of one or more devices 111 is transferred to a supporting plate 121, which may be AlN, SiC, Si, Cu, CuW, and the like. As shown in FIGS. 1l 1m, the solder 122 for bonding the bar 115 is disposed on the supporting plate 121, wherein the solder 122 may be Au—Sn, Su—Ag—Cu, Ag paste, and the like. Then, a p-electrode 110 is bonded to the solder 122. The devices 111 can also be flip-chip bonded to the plate 121.

In the case of bonding LED chips to the supporting plate 121, the size of the supporting plate 121 does not matter, and it can be designed as desired.

### Supporting Plate With Trenches

It is preferable that the supporting plate 121 have trenches or other means for dividing the devices 111. This structure is useful when dividing the supporting plate 121 into the bars 115 or chips. After dividing the supporting plate 121, the devices 111 can be fabricated into modules, such as lighting modules. The trenches in the supporting plate 121 guide the division into the devices 111. The trenches can be formed by a wet etching method and mechanically processed before the device 111 is mounted. For example, if the supporting plate 121 is made of Silicon, wet etching can be used to form the trenches. Using the trenches in this manner, reduces the lead time of the process.

### Alternative Embodiments

The following describes alternative embodiments of the present invention.

### First Embodiment

An III-nitride-based semiconductor device 111 and a method for manufacturing thereof, according to a first embodiment are described. In this embodiment, the device 111 may comprise a micro-LED or VCSEL.

Generally, a substrate 101 is first provided, and a growth restrict mask 102 that has a plurality of striped openings areas 103 is formed on the substrate 101. The coloring layer 105B, which is a high-speed III-nitride ELO layer, is coalesced between adjacent layers 105B. The center of the void region 107 is removed by a dry etching method. Bars 115 of devices 111 are bonded to the supporting plate 121 to remove the bars 115 from the substrate 101. Finally, the coloring layer 105B is removed by a wet etching method.

FIGS. 1a-1m illustrate the specific process steps and structures involved in this method. These process steps and structures are described in more detail below.

Step 1: This step involves providing a substrate 101, as shown in FIG. 1a, and then depositing a growth restrict mask 102 on the substrate 101 with a remaining surface exposed by opening areas 103 in the growth restrict mask 102, as shown in FIG. 1b.

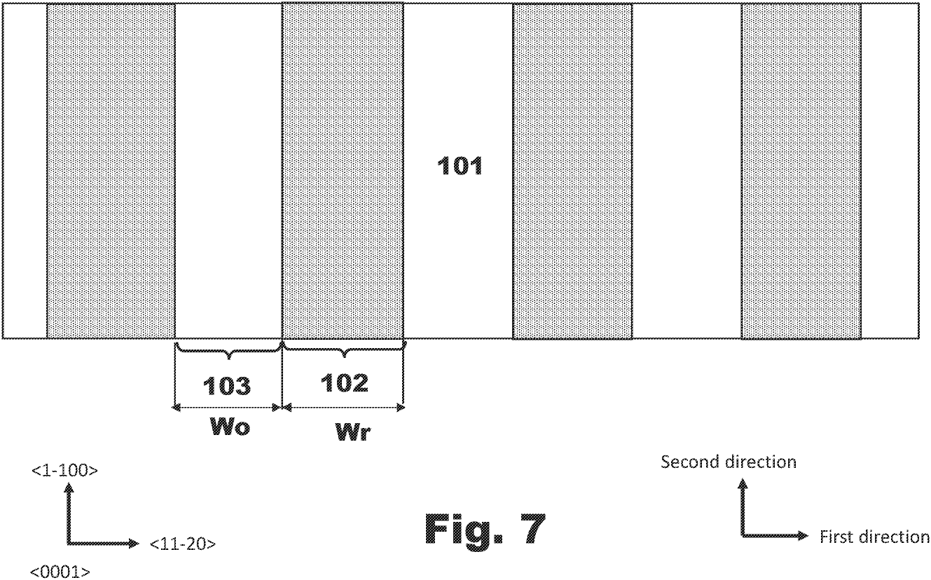

Moreover, FIG. 7 is a top plan view of a growth restrict mask 102 deposited on a substrate 101. The width Wr of the stripes in the growth restrict mask 102 is 30 µm – 200 µm, and more preferably, 30 µm–120 µm. The width Wo of the opening areas 103 is 2 µm–60 µm, and more preferably, 3 µm – 40 µm.

In place of the III-nitride substrate 101, the present invention can use various kinds of hetero-substrates 101A with III-nitride templates 101B, such as III-nitride templates 101B on a sapphire substrate 101A, a silicon substrate 101A, a SiC substrate 101A, and so on. It is also possible to grow the initial growth layer 105A and coloring layer 105B directly on the growth restrict mask 102 deposited on a hetero-substrate 101A.

Step 2: This step involves growing an initial growth layer 105A on the substrate 101 using the growth restrict mask 102, such that the growth extends in a direction parallel to the striped opening areas 103 of the growth restrict mask 102, and the height of the initial growth layer 105A is higher than the height of the growth restrict mask 102, as shown in FIG. 1c. In this case, it is much better to be able to obtain the uniform shape of the coloring layer 105B easily in wide range of growth conditions. Like FIG. 7, FIG. 1c also shows the width Wr of the stripes in the growth restrict mask 102, as well as the width Wo of the opening areas 103.

MOCVD is used for the epitaxial growth of the initial growth layer 105A. Trimethylgallium (TMGa) is used as the III elements source; ammonia (NH₃) is used as the raw gas to supply nitrogen; and hydrogen (H₂) and nitrogen (N₂) are used as a carrier gas of the III elements sources. It is important to include hydrogen in the carrier gas to obtain a smooth surface to the epilayers. The growth temperature is about 900 degree to 1200 degree. The thickness of the initial growth layer 105A is about 1 µm - 5 µm.

Step 3: This step involves growing the coloring layer 105B, as shown in FIG. 1d. The growth conditions are almost same as with the initial growth layer 105A. However, to increase the speed of the lateral growth, the V/III ratio is set under 500. Especially, NH₃ flow rate should be decreased. In this case, the growth speed of the vertical direction is suppressed, and the lateral growth speed is enhanced. The shape of the edge of the coloring layer 105B becomes an inverted taper facet.

If growth of the coloring layer 105B is terminated before coalescence, then no-growth regions 104 are formed. Alternatively, growth may be continued until the coloring layer 105B coalesces, so that no-growth regions 104 are not formed.

As shown in FIG. 1e, the coloring layer 105B has coalesced, but contains voids 107, which may or may not result in a depressed portion 117. The inverted taper facets of the coloring layer 105B help form the voids 107. These voids 107 can release the stress from the growth restrict mask 102, which can prevent cracks in the epilayers.

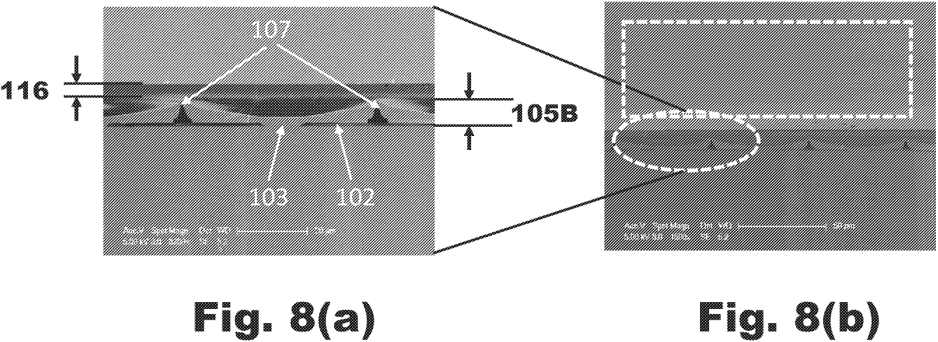

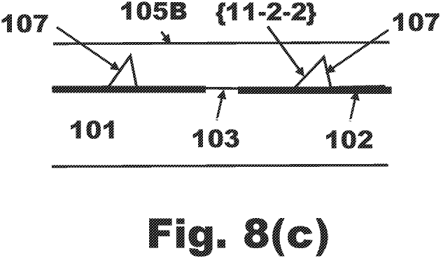

The inverted taper facet has a {11-2-2} orientation, as shown in the SEM images of FIGS. 8a 8b 8c. During the growth of the coloring layer 105B, the {11-2-2} facet appears, but just before coalescence. The {11-2-2} facet is inclined due to the growth condition change, which is caused by closing each layer 105B. However, the inverted taper facets help to create triangular voids 107 in the coloring layer 105B. Once the layers 105B coalesce in this situation, the triangular voids 107 do not disappear, even though the growth continues.

MOCVD is used for the epitaxial growth of the initial growth layer 105A and coloring layer 105B. Trimethylgallium (TMGa) is used as the III elements source; ammonia (NH₃) is used as the raw gas to supply nitrogen; and hydrogen (H₂) and nitrogen (N₂) are used as a carrier gas of the III elements sources. It is important to include hydrogen in the carrier gas to obtain a smooth surface to the epilayers.

The thickness of the initial growth layer 105A is about 1 µm - 10 µm. The initial growth layer 105A may comprise a GaN or AlGaN, InGaN, InAlGaN layer in order to obtain a smooth surface.

The triangular voids 107 can effectively release the stress from the difference of the thermal expansion coefficient between GaN layers 105A, 105B, and the growth restrict mask 102, such as SiO₂, SiN and so on. The voids 107 made by doing this are placed directly on the growth restrict mask 102, and are surrounded by the growth restrict mask 102 and the layers 105B, which can effectively release the stress from the growth restrict mask 102. Moreover, the triangle shape of the voids 107 is much preferable in terms of releasing the stress because of the height of the voids 107 are higher than the voids 107 made without the growth restrict mask 102. In addition, the voids 107 can be formed without growth interruption.

After the coloring layers 105B coalesce, the voids 107 prevent the occurrence of the cracks in the coloring layers 105B. Moreover, the coloring layers 105B substantially cover the growth restrict mask 102, which avoids compensating p-type device layers 106 by the decomposition of atoms from the growth restrict mask 102.

Step 4: As shown in FIG. 1f, this step involves growing the flattening layer 116 on the coloring layer 105B to level the surface of the epilayers. As noted in Step 3, the coloring layer 105B may have a depressed portion 117 at an upper portion of the voids 107 due to the existence of the voids 107.

The flattening layer 116 is grown under conditions having a higher V/III ratio as compared to the coloring layer 105B, for the following reasons. First, distortion of the surface roughness is avoided. Second, this avoids coloring of the flattening layer 116. Third, this enhances the vertical direction growth for the sake of leveling the surface as soon as possible.

In this step, the flattening layers 116 are unintentionally doped (UID) layers or Si-doped layers. In addition, Mg-doped layers or co-doped layers of Mg and Si can be used as a flattening layer 116. The growth of a III-nitride layer containing Mg effectively buries a depressed area 117 at the center of the void region 107.

Step 5: This step involves growing the III-nitride semiconductor device layers 106 on the coloring layer 105B or flattening layer 116, as shown in FIG. 1g. Leveling the surface of the epilayers helps to prevent fluctuations in an emitting wavelength from an active region 108. If the surface is not level, the Indium or Aluminum composition are varied corresponding to the surface roughness. Leveling the surface refers to the growth of the active region 108.

MOCVD is used for the epitaxial growth of the III-nitride semiconductor device layers 106. Trimethylgallium (TMGa), triethylgallium (TEG), trimethylindium (TMIn) and triethylaluminium (TMAl) are used as III elements sources; ammonia (NH₃) is used as the raw gas to supply nitrogen; and hydrogen (H₂) and nitrogen (N₂) are used as a carrier gas of the III elements sources.

Saline and Bis(cyclopentadienyl)magnesium (Cp₂Mg) are used as n-type and p-type dopants, respectively. The pressure setting typically is 50 to 760 Torr. The III-nitride semiconductor device layers 106 are generally grown at temperature ranges from 700 to 1250° C.

For example, the growth parameters include the following: TMG is 12 sccm, NH₃ is 8 slm, carrier gas is 3 slm, SiH₄ is 1.0 sccm, and the V/III ratio is about 7700. These growth conditions are only one example, and the conditions can be changed and optimized for each of the III-nitride semiconductor device layers 106.

Step 5′: If the flattening layer 116 is not grown or it does not obtain a flat surface, it is possible to polish the surface of the flattening layer 116 or the coloring layer 105B to further flatten the surface, before growth of the III-nitride semiconductor device layers 106. For example, CMP can be used.

Step 6: This step involves fabricating a device 111 at a flat surface region of the III-nitride semiconductor device layers 106 by conventional methods, as shown in FIG. 1h, wherein a current blocking layer 109, p-electrode 110, ridge structure 112, etc., are disposed on the island-like the III-nitride semiconductor device layers 106 at pre-determined positions.

Step 7: This step involves etching the III-nitride semiconductor device layers 106, the flattening layer 116, and the coloring layer 105B, by a conventional dry etch method and photo-lithography method, as shown in FIGS. 1i-1j. A photoresist 118 is deposited, as shown in FIG. 1i, and then the center of the void region 107 is etched as an etching region 114, as shown in FIG. 1j. The bottom of the etching region 114 should reach the top of the void 107 in order to divide the epilayers into the bars 115. Around the center of the void region 107 are many defects, which are generated when coalescing the coloring layer 105B. It is much better to remove the portion having many defects in the upper portion of the void region 107. The width L of the etching region 114 is preferably over 3 µm.

Then, utilizing the etching region 114, the growth restrict mask 102 can be dissolved using a wet etchant, such as Hydrofluoric Acid (HF) and Buffered HF. This helps to remove the bars 115 from the substrate 101, as shown in FIG. 1k.

Step 8: This step describes the removal of the bar 115, which can be adapted from any number of methods. In one method, the bars 115 of the devices 111 are removed from the substrate 101 using the supporting plate 121 to bond the bars 115, as shown in FIG. 1l. It is preferable that the supporting plates 121 are comprised of high thermal conductivity materials and/or high leveled surface flatness materials. The supporting plate 121 has a solder 122 to bond the metals, e.g., p-electrode 110, disposed on the bars 115. Generally, the bonding temperature is about 300° C., depending on the kind of metal. The substrate 101 bonded to the supporting plate 121 is heated. After melting the metals and the solder, the substrate 101 and the supporting plate 121 are cooled down. At this time, the difference in the thermal expansion coefficiency between the substrate 101 and the supporting plate 121 applies stress to a connecting point of the initial growth layer 105A, as shown in FIG. 1l. Then, the stress breaks the remaining bond at the initial growth layer 105A. The bars 115 can be transferred to the supporting plate 121.

Step 9: This step involves removing the coloring layer 105B. As shown in FIG. 1m, the bars 115 are mounted on the supporting plate 121 in a junction down disposition. In the case of a c-plane polar III-nitride device 111, the N-polar surface of the bar 115, which is easy and fast to polish or etch, is in a face-up disposition. Moreover, since the coloring layer 105B contains a large amount of impurities, e.g., over 1x10¹⁸ cm⁻³, the etching speed is increased, which makes the coloring layer 105B easy to etch.

In this invention, the coloring layer 105B should be under 18 µm in thickness, more preferably under 10 µm, for the sake of the reduction in process time and the gain in yield. The present invention allows these to be realized. As explained above, during the growth of the coloring layer 105B, the lateral direction of the growth is increased, and the vertical direction of the growth is suppressed, which means that the coloring layer 105B can be grown thinner, which makes the etching of the coloring layer 105B easy.

As shown in FIG. 1n, a very rough surface for the coloring layer 105B can be obtained using an alkali etchant, such as KOH, NaOH, TMAH and so on, for removing the coloring layer 105B from the bar 115, in case of polar c-plane III-nitride device 111. This rough surface is intended to enhance extraction of the light emitted from an active region 108 of the device layers 106. Thus, the elimination of the coloring layer 105B can also make structures for enhanced light extraction at the same time, which can reduce processing cost and time. It is also possible to use a photo-electro-chemical (PEC) etching method to remove the coloring layer 105B and roughen the surface.

Alternatively, the coloring layer 105B may be removed by CMP to obtain a flat surface, as shown in FIG. 1o. A DBR 123 may be disposed on the polished surface for use in a VCSEL device 111. The DBR 123 for the VCSEL requires a very flat surface for a reduction of the light scattering at the interface between the DBR 123 and the polished surface.

Step 10: This step involves fabricating an n-electrode on the bar 115 of the devices 111. After removing the coloring layer 105B, with the bar 115 is attached to the supporting plate 121 using solder 122 in an upside-down manner, an n-electrode (not shown) can be disposed on the back side of the III-nitride device layers 106 or the flattening layer 116 using a metal mask method. When the bar 115 height is over 10 µm, it is preferable to use the metal mask method to dispose the n-electrode.

Typically, the n-electrode is comprised of the following materials: Ti, Hf, Cr, Al, Mo, W, Au. For example, the n-electrode may be comprised of Ti—Al—Pt—Au (with a thickness of 30-100-30-500 nm), but is not limited to those materials. The deposition of these materials may be performed by electron beam evaporation, sputter, thermal heat evaporation, etc.

The n-electrode also can be disposed on a top surface, which is the same surface made for a p-electrode 110.

Step 11: This step involves breaking the supporting plate 121 and bars 115 into devices 111, as shown in FIG. 1p, after disposing the n-electrode. This step can use a breaking method, as well as other conventional methods, but it is not limited to these methods. It is preferable that a blade contact a side of the bar 115 which is not formed by a dividing support region, at the position of the dividing support region.

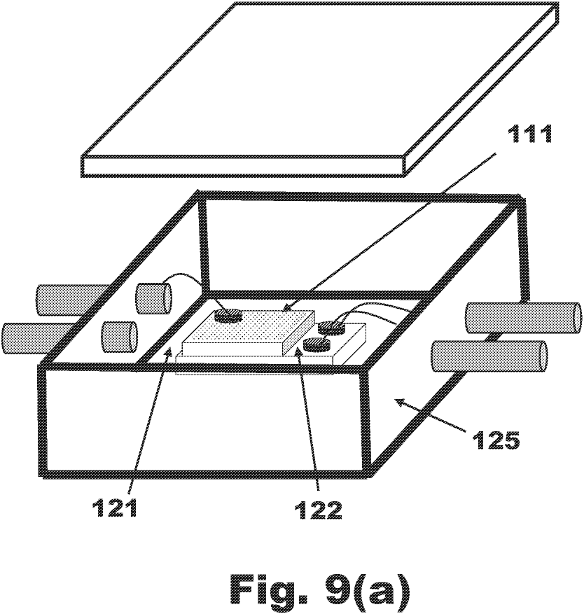

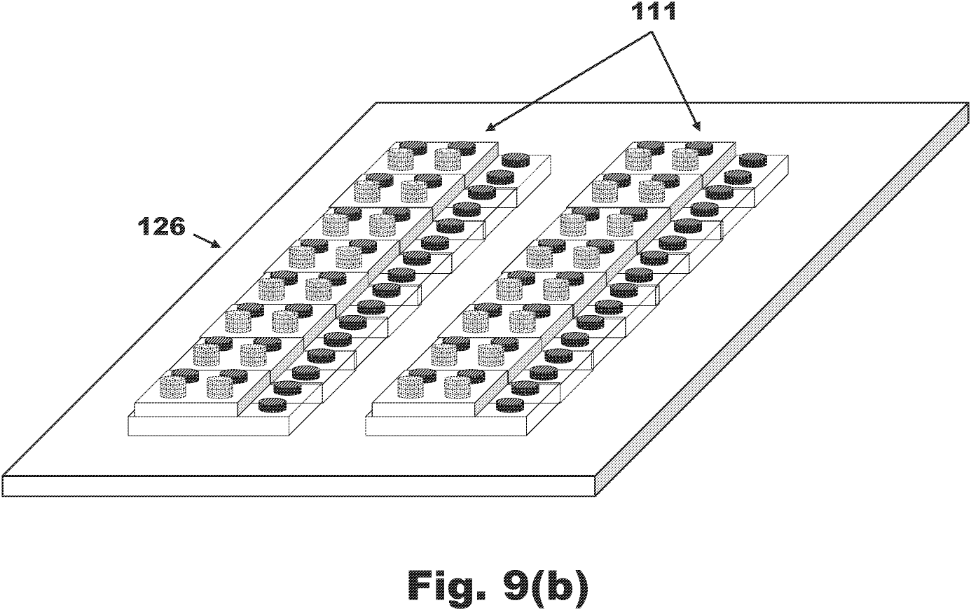

Step 12: This step involves mounting each device 111 or array of devices 111 in a package 125 or on a heat sink plate 126, as shown in FIGS. 9a 9b. Generally, a micro-LED or a VCSEL is very small size chip. To obtain high power output, it is better to mount the devices 111 in a package 125 or on a heat sink plate 126.

For example, as shown in FIG. 9a, the device 111 is mounted in a package 125. The solder 122 (Au—Sn, Sn—AG—Cu and the like) or the bonding metal, which are disposed at the bottom of the package 125, are bonded by wires to the solder 122 on the supporting plate 121. The pins of the package 125 are connected to the solder 122 on the supporting plate 121 by the wires. By doing this, current from an outside supply can be applied to the devices 111. This is more preferable than bonding between the package 125 and the supporting plate 121, which is performed by metal bonding, such as Au—Au, Au—In, etc., bonding. This method requires a flatness at the surface of package 125 and at the back side of the heat sink plate 126. However, without the solder 122, this configuration accomplishes a high thermal conductivity and low temperature bonding. These are big advantages for the device process.

Moreover, a phosphor can be set outside and/or inside the package 125. By doing this, this module can be used as a light bulb or a head light of an automobile.

### Substrate Recycling

As set forth herein, these processes provide improved methods for obtaining laser diode devices, VCSELs, LEDs, and photo diode devices. In addition, once the device is removed from the substrate, the substrate can be recycled a number of times by polishing the surface which is removed the devices. This accomplishes a goal of the eco-friendly production and low-cost modules. These devices may be utilized as lighting devices, such as light bulbs, data storage equipment, optical communications equipment, such as Li-Fi, etc.

It is difficult to package with plurality different types of lasers in one package so far. However, this method can overcome this issue due to being able to do an aging test without packaging. Therefore, in case of mounting the different types of devices in one package it can be easily to mount.

In addition, as shown in FIG. 9b, it can make array formation of the devices 111, which may be VCSELs, micro-LEDs, etc. In this case, this array can be use displays and signages etc.

### Second Embodiment

The second embodiment is almost the same as the first embodiment, except for the removing method.

In Step 7, the removing method may also remove an upper part of the opening area 103 as well as the center of the void region 107 by the removal of the bars 115. This is shown by FIGS. 3a-3g.

The etching of the initial growth layer 105A, the flattening layer 116, and the coloring layer 105B can be performed by conventional photolithography and a dry etch method, as shown in FIGS. 3a 3b. A photoresist 118 is patterned to etch the portion above the voids 107 and the opening areas 103. The etching can use other materials, such as etching masks including dielectric masks, metal masks and so on.

The depth of the etching region 114 needs to reach the top of the growth restrict mask 102 at the opening areas 103 to separate the bars 115 from the substrate 101, as shown in FIG. 3b. It is preferable that the width of the etching region 114 at the opening area 103 is larger than the width of the opening area 103 to separate the bar 115 from the substrate 101. At this time, the bars 115 are on the growth restrict mask 102. The bonding strength the interface between the bottom of the coloring layer 105B and the surface of the growth restrict mask 102 is very weak. If a stress or force is applied to the bars 115, the bars 115 can be easily removed.

As a next step, the photoresist 118 should be removed using solvents, such as acetone and ethanol, with ultra-sonic cleaning. During this cleaning, the bars 115 might be removed.

If the etching region 114 at the opening areas 103 reaches the growth restrict mask 102, then the bars 115 can be separated from the substrate 101. The bars 115 may be hooked to the substrate 101 by a hooking layer 119, such as a dielectric mask comprised of SiO₂, SiN, SiON, Al₂O₃, AlON, AlN, ZrO₂, Ta₂O₅, etc., as shown in FIGS. 3c 3d. Dissolving the photoresist 118 can lift off the hooking layer 119 from the photoresist 118.

The hooking layer 119 has two purposes. One is to fix the bar 115 on the growth restrict mask 102 temporarily to avoid peeling off the bar 115 when the photoresist 118 is dissolved by solvent followed by ultra-sonic cleaning. Another is that using dielectric materials as a hooking layer 119 can passivate the side facets of the bar 115. The side facets of the bar 115 sometimes are damaged from dry etching, depending on the etching conditions. If the width of the bar 115 is narrow, leakage current occurring at the side facet of the bar 115 due to etching damage might affect the characteristics of the devices 111. The dielectric material can be chosen to reduce side facet’s leakage current, for example, SiO₂, SiN, SiON, Al₂O₃, AlON, AlN, ZrO₂, Ta₂O₅, etc.

The strength of the fixing of the bar 115 can be varied by changing the thickness of the hooking layer 119. For example, the strength can be controlled in order not to remove the bars 115 during ultra-sonic cleaning, the lift-off process, or some other process.

The bars 115 also can be removed using the supporting plate 121, as shown in FIG. 3e. The solder 122 on the supporting plate 121 can bond the bars 115 to the supporting plate 121. Generally, the bonding process increases the temperature, for example, the use of Au—Sn solder 122 results in a bonding temperature of about 280° C. After bonding, when the temperature is reduced to room temperature, the stress from different thermal expansion coefficients can break the hooking layer 119 at breaking points 120, as shown in FIG. 3e, and the bars 115 and devices 111 can be removed from the substrate 101, as shown in FIG. 3f.

The coloring layer 105B appears at the back-surface of the bars 115 and devices 111 opposite the supporting plate 121. The coloring layer 105B can then be removed by CMP, either in its entirety or partially, which reduces absorption losses by the coloring. In the example shown in FIG. 3g, the coloring layer 105B has been fully eliminated, exposing the flattening layer 116.

### Third Embodiment

The third embodiment is performed without coalescence of the coloring layer 105B. This embodiment has the following features:
1. Using a hetero-substrate 101A with a GaN template or underlayer 101B on its surface, wherein the base hetero-substrate 101A is sapphire.
2. The coloring layers 105B are not coalesced with each other.
3. A planarization process can be used in order to bond the bars 115 to the supporting plate 121.
4. A laser lift-off process is used to remove the bars 115.

This embodiment uses gaps between adjacent coloring layers 105B, herein referred to as no-growth regions 104. The no-growth region 104 has an important role in the release of internal stress, which can prevent cracks from occurring. In this embodiment, the height of the bar 115 may have a fluctuation as compared to the coalescence version. The height fluctuation sometimes makes the bonding process difficult. This embodiment can bond the bars 115 to the supporting plate 121 even when the bars 115 have a height fluctuation.

This embodiment is explained in FIGS. 2a-2q. The growth restrict mask 102 is disposed on the base substrate 101A with a GaN underlayer 101B, as shown in FIG. 2a. The base substrate 101A is a hetero-substrate, such as a sapphire substrate. The thickness of the GaN underlayer 101B preferably ranges from 0.4 µm to 5 µm. The initial growth layers 105A are grown on the GaN underlayer 101B.

Then, the coloring layers 105B are grown continuously, as shown in FIG. 2b. In this case, the growth of the coloring layers 105B stops before the coloring layers 105B coalesce to each other, resulting in no-growth regions 104.

Then, the flattening layers 116 are grown on and surrounds the coloring layers 105B, as shown in FIG. 2c, wherein the flattening layers 116 act as both the flattening layer 116 and a buffer layer. The coloring layer 105B sometimes has a rough surface, depending on the growth conditions. Thus, the flattening layer 116 can improve the surface roughness of the coloring layer 105B. Later, when etching or polishing the coloring layer 105B, the flattening layer 116 can protect the III-nitride semiconductor device layers 106 as a buffer layer from the etching or polishing. In a large size wafer, the amount of etching and polishing has an in-plane distribution. Thus, the thickness of the flattening layer 116 is preferably set to at least 0.5 µm for the protection of the device layers 106.

As noted above, the coloring layer 105B does not coalesce, which results in the no-growth region 104. This no-growth region 104 causes a decomposition of the growth restrict mask 102. To suppress the decomposition, the width of the no-growth region 105 is set to be narrow, for example, under 20 µm, and more preferably, under 10 µm.

Alternatively, a cover layer 127 can be used to avoid decomposition of the growth restrict mask 102, as shown in FIG. 2d, by disposing the cover layer 127 on the growth restrict mask 102 within the no-growth region 104. The cover layer 127 should be a high melting point metal, such as Pt, W, Mo, etc., or a dielectric layer that does not contain an n-dopant, such as TiN, etc.

The III-nitride semiconductor device layers 106 are grown on the flattening layer 116, as shown in FIG. 2e. It is not necessary to grow the flattening layer 116 when the bottom layer of the III-nitride semiconductor device layers 106 is thicker, because the bottom layer can protect the active region 108. The distance between the surface of the coloring layer 105B and the bottom of the active region 108 should be over 0.5 µm at least to protect the active region 108 against an etching or polishing process.

The fabrication of the device 111 is implemented on the III-nitride semiconductor device layers 106, as shown in FIG. 2f, wherein a current blocking layer 109, p-electrode 110, ridge structure 112, etc., are disposed on the island-like III-nitride semiconductor device layers 106 at pre-determined positions. In the case where the device 111 is a micro-LED, highly reflective contact metal layers, such as Ni (0.7 nm) / Ag (250 nm) /Ni (200 nm) can be used for the p-electrode 110. In this embodiment, the micro-LEDs are mounted with the junction down, and the highly reflective contact metal layers improve light extraction.

In this embodiment, the no-growth region 104 services as an isolation trench, which may be filled with an epoxy or photoresist for surface planarization. In order to remove the devices 111 from the substrate 101A, the filling of the isolation trench filling can eliminate cracking and fracturing of epilayers during the laser lift-off process from the substrate 101A.

This is illustrated in FIG. 2g, where a 35 µm thick epoxy-based SU-8 2025 photoresist 124 made by Micro Chem™ was spin coated on the top surface of the bars 115 with a rotation rate of about 2000 RPM for 30 seconds (s). A pre-bake and a post-bake was implemented at 65 degrees for 2 minutes (min) and 95 degrees for 5 min, respectively, for the evaporation of a solvent in the SU-8. Then, UV-exposure was conducted conventionally. The post-bake was conducted again at 95 degree for 3 min. Non-polymerized photoresist 124 was removed in the developing step by immersing the wafer in a MicroChem™ SU-8 developer for 5 min. The photoresist 124 was baked at 250 degrees for 30 min to harden the photoresist 124. After that, seed metal layers (not shown) were disposed for electroplating, namely, Ti (50 nm) / Cu (500 nm) seed metal layers were evaporated on top of the electrode of the device 111.

A 30 µm-thick copper layer 128 was electroplated, as shown in FIG. 2h. The copper layer 128 and photoresist 124 were polished to level the surface until the thickness of the copper layer 128 is about 20 µm, as shown in FIG. 2i. By doing this, the planarization of the surface is completed.

Leveling the surface makes it easier to bond the bars 115 to the supporting plate 121, as shown in FIG. 2j. The supporting plate 121 is comprised of AlN with vias 129 filled with Cu and a pad electrode 130, as shown in FIG. 2j. Bonding metal layers of Ti (100 nm) / Ni (100 nm) / AuSn (1500 nm) 131 are disposed on the copper layer 128.

The wafer was bonded onto the supporting plate 121 at 300 degree for 30 min, as shown in FIG. 2k.

In this embodiment, laser lift-off methods may be implemented to remove the bars 115. However, the methods used are different from a conventional laser lift-off method, due to the use of epitaxial lateral overgrowth.

The bars 115 contact the substrate 101A through the opening areas 103, which are filled by the initial growth layer 105A, as shown in FIG. 2l. A laser lift-off removes the bar 115 from the substrate 101A by irradiating the initial growth layer 105A in the opening area 103 using a KrF excimer laser 132 (with a wavelength of 248 nm).

Note that the opening area 103 is very narrow as compared to the substrate 101A. A conventional laser lift-off method has to irradiate the entire wafer to remove the device layers 106 from the substrate 101A.

Preferably, the substrate 101A is a sapphire substrate 101A, which is transparent to the KrF excimer laser 132.

In this embodiment, using the ELO method and the laser lift-off method can reduce the laser 132 irradiation time, which leads to the reduction of the process cost and the longevity of the KrF excimer laser 132. It is preferable that at least the area which is irradiated by the laser 132 is wider than opening area 103.

Moreover, to improve the yield of the removal using the laser lift-off method, the underlayer 101B is thinner than usual. It is preferable the thickness of the underlayer 101B is under 4 µm, and more preferably under 2 µm, for the separation of the bar 115 from the substrate 101A. It is possible not to grow the underlayer 101B, and instead the coloring layer 105B is grown directly on the sapphire substrate 101A surface, which is easy to remove.

FIG. 2m shows the substrate 101, underlayer 101B and growth restrict mask 102 following the laser lift-off. The fabrication sequence after the laser lift-off, uses an HCl solution treatment to remove any residual Ga from the laser lift-off.

Then, the next step is the elimination of the coloring layer 105B, which is the same as described above in Step 9. In this case, CMP can be used, as shown in FIG. 2n, but dry and wet etching method also can be used.

After the coloring layer 105B is removed, as shown in FIG. 2o, DBR layers 123 may be disposed on the backside of the bars 115, since the surface of the flattening layer 116 is very smooth due to polishing by CMP. As a result, this embodiment can be used to fabricate VCSEL devices 111.

As shown in FIG. 2p, this embodiment can also be used to make LED devices 111 by depositing an n-electrode 113 on the backside of the bars 115, wherein the supporting plate 121 is then divided into the bars 115.

### Side Facet Active Region

In this embodiment, the coloring layer 105B and the III-nitride semiconductor device layers 106 do not coalesce. However, the active region 108 of the III-nitride semiconductor device layers 106 bends, as shown in FIG. 2q, due to the existence of the no-growth region 104 (not shown). This portion of the active region 108 is called a side facet active region. Since this side facet active region absorbs light from the active region 108, the efficiency of the device 111 decreases. Needless to say, the side facet active region should be removed for the sake of device 111 efficiency. Moreover, the side facet active region should be removed to reduce cross-talk effects between adjacent micro-LED devices 111.

### Planarization Method

Planarization using a photoresist 124 resist reduces the fluctuations in the bar 115 height, which improves bonding yields. Moreover, planarization can reduce the process time for the laser lift-off process, since the irradiation area for removing the bars 115 is limited. Planarization using the photoresist 124 also can be used in the case of coalescence of the coloring layer 105B. For example, after forming the trench in Step 7, the planarization process can be utilized. The planarization is especially useful when the no-growth region 104 is in existence.

### Laser Lift-Off Process and ELO Technique

The laser lift-off method and ELO technique provide the following advantages:
1. Using the ELO technique reduces defect density drastically, even in the case of a hetero-substrate 101A, such as a sapphire substrate, etc.
2. Bars 115 can be removed from the substrate 101 using the laser 132 to irradiate only the opening areas 103. Scanning the laser 132 light along the opening areas 103 can drastically reduce both process time and cost.
3. Since the irradiation area is only the opening areas 103, the pollution of Ga metals does not affect any remaining area of the bars 115. For example, the back surface of the bar 115 is protected by contacting the growth restrict mask 102 during the irradiation by the laser 132. A remaining area is marked by a dashed line, as shown in FIG. 2l. Even if the laser 132 irradiates the remaining area, the GaN underlayer 101B in the remaining area absorbs the laser 132 light. Thus, the back-side surface of the bar 115 marked with the dashed line has no damage.

### Elimination of the Coloring Layer

The bars 115 are mounted on the supporting plate 121 in a junction down disposition. In the case when using polar c-plane III-nitride semiconductor device layers 106, the top surface of the bar 115 is N-polar, which is easier and fasted to polish and etch. Moreover, since the coloring layer 105B contains a large amount of impurities, etching speed is increased.

In this invention, the coloring layer 105B should have a thickness under 18 µm, and more preferably 10 µm, in order to reduce process time and gain a high yield. As noted above, during the growth of the coloring layer 105B, the lateral direction of the growth increases in speed, and the vertical direction of the growth is suppressed, which allows the coloring layer 105B to be grown thinner. This makes etching the coloring layer 105B easy.

As shown in FIG. 1n, a rough surface can be obtained using an alkali etchant, such as KOH, NaOH, TMAH and so on, for removing the coloring layer 105B from polar c-plane III-nitride semiconductor device layers 106. This also helps in the extraction of light emitted from the active region 108. As result, elimination of the coloring layer 105B can also create the structure for the light extraction at the same time, which can reduce process cost and time. Also as noted above, PEC etching can be used as well.

Another option is to remove the coloring layer 105B by CMP to obtain the flat surface, as shown in FIG. 1m. A DBR 123 may be disposed on the polished surface for a VCSEL device 111, as shown in FIG. 1o, wherein the DBR 123 for the VCSEL device 111 requires a very flat surface for the reduction of light scattering at the interface between the DBR 123 and the polished surface.

The effect is to reduce absorption by the coloring layer 105B due to elimination of at least part of the coloring layer 105B.

### Process Steps

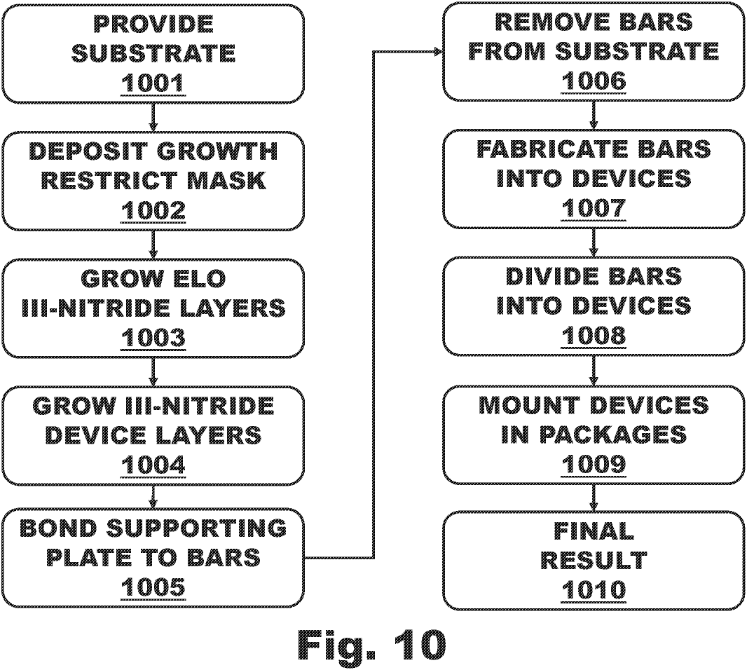

FIG. 10 is a flowchart that illustrates a method for removing devices 111 from a substrate 101, 101A, 101B using an ELO technique, wherein: one or more bars 115 comprised of III-nitride semiconductor layers 105A, 105B, 116, 106 are formed on the substrate 101, 101A, 101B, and the device 111 structures are formed on the bars 115; at least one supporting plate 121 is bonded to the bars 115, and the supporting plate 121 is used to remove the bars 115 from the substrate 101, 101A, 101B; the supporting plate 121 is used to divide the bars 115 into one or more device 111 units; and the device 111 units are arranged and mounted into one or more packages 125. The steps of the method are described in more detail below.

Block 1001 represents the step of providing a base substrate 101. In one embodiment, the base substrate 101 is a III-nitride based substrate 101, such as a GaN-based substrate 101, or a foreign or hetero-substrate 101A, such as a sapphire substrate 101A. This step may also include an optional step of depositing a III-nitride template or underlayer 101B on or above the substrate 101A, wherein the III-nitride template or underlayer 101B may comprise a buffer layer or an intermediate layer, such as a GaN template or underlayer 101B.

Block 1002 represents the step of depositing a growth restrict mask 102 on or above the substrate 101, i.e., on the substrate 101, 101A itself or on the template or underlayer 101B. The growth restrict mask 102 is patterned to include a plurality of opening areas 103.

Block 1003 represents the step of performing an epitaxial lateral overgrowth (ELO) of one or more III-nitride layers 105A, 105B on or above the growth restrict mask 102, wherein the III-nitride layers 105A comprise an initial growth layer 105A and the III-nitride layers 105B comprise a coloring layer 105B.

In one embodiment, the III-nitride layers 105B are grown directly on the growth restrict mask 102, to cover a growth restrict mask 102, wherein the coloring layers 105B has a thickness is less than about 18 µm.

The III-nitride layers 105B are grown with a low V/III ratio of less than 500 resulting in high-speed lateral growth as compared to low-speed vertical growth, wherein the high-speed lateral growth reduces a cost of a device, because of a decrease in growth time and source material used. Specifically, the high-speed lateral growth suppresses vertical growth, which reduces an aspect ratio between a width and height of the III-nitride layers 105B, thereby allowing for a thin device 111.

The high-speed lateral growth reduces a side facet area and thus decreases an amount of the light extracted from the side facet area. The high-speed lateral growth also reduces fluctuations in the height of the III-nitride layers 105B. In addition, the high-speed lateral growth permits wider periods between opening areas 103 in the growth restrict mask 102 deposited on a substrate 101, 101A, 101B without coalescence regions.

The III-nitride layer 105B contains a large amount of impurities, over 1 × 10¹⁸ cm⁻³, which results in the III-nitride layer 105B comprising a coloring layer 105B, and the coloring layer 105B absorbs and scatters light from an active region 108 due to the large amount of impurities. In addition, at least one of the coloring layers 105B includes a void 107, which reduces stress.

This step also includes the optional steps of allowing adjacent ones of the ELO III-nitride layers 105A, 105B to coalesce to each other, or stopping the growth of the ELO III-nitride layers 105A, 105B before adjacent ones of the ELO III-nitride layers 105A, 105B coalesce to each other.

Block 1004 represents the step of growing one or more III-nitride semiconductor device layers 106 on or above the initial growth layers 105A and the coloring layers 105B, thereby forming a bar 115 on the substrate 101 comprised of the coloring layers 105B and the III-nitride semiconductor device layers 106. Additional device 111 fabrication may take place before and/or after the bar 115 is removed from the substrate 101.

Block 1005 represents the step of bonding the supporting plates 121 to the bar 115. The supporting plate 121 is used to remove the substrate 101, 101A, 101B and coloring layers 105B from the device 111 structures when the bars 115 are removed from the substrate 101, 101A.

Block 1006 represents the steps of removing the bar 115 from the substrate 101, 101A, 101B. This step eliminates at least a part of at least one of the coloring layers 105B from the bars 115 of the devices 111, thereby reducing absorption losses.

Block 1007 represents the step of fabricating the bars 115 into devices 111 after the bar 115 is removed from the substrate 101, 101A.

Block 1008 represents the step of dividing the bar 115 into one or more devices 111 by cleaving at the dividing support regions formed along the bar 115.

Block 1009 represents the step of mounting the devices 111 with the supporting plates 121 in a package 125 or module.

Block 1010 represents the resulting product of the method, namely, one or more III-nitride based semiconductor devices 111 fabricated according to this method, as well as a substrate 101, 101A that has been removed from the devices 111 and is available for recycling and reuse.

The devices may comprise one or more ELO III-nitride layers 105A grown on or above a growth restrict mask 102 on a substrate 101, wherein the growth of the ELO III-nitride layers 105A is stopped before adjacent ones of the ELO III-nitride layers 105A coalesce to each other. The devices may further comprise one or more III-nitride regrowth layers 105B and one or more additional III-nitride semiconductor device layers 106 grown on or above the ELO III-nitride layers 105A and the substrate 101.

### Advantages and Benefits

The present invention includes the following advantages and benefits.
1. An ELO layer 105A with no defects and device layers with a wide area.
2. High-speed lateral growth rate using a low V/III ratio.
3. Compensation of p-type layers by decomposition of the growth restrict mask 102 can be avoided.
4. The coloring layer 105B can be removed by polishing or etching.
5. The polishing or etching obtains a very smooth back side surface of a bar 115 of the device 111.
6. A laser lift off process makes the bar 115 easy to remove.

### Modifications and Alternatives

A number of modifications and alternatives can be made without departing from the scope of the present invention.

For example, the present invention may be used with III-nitride substrates of other orientations. Specifically, the substrates may be basal nonpolar m-plane {1 0 -1 0} families; and semipolar plane families that have at least two nonzero h, i, or k Miller indices and a nonzero 1 Miller index, such as the {2 0 -2 -1} planes. Semipolar substrates of (20-2-1) are especially useful, because of the wide area of flattened ELO.

Moreover, the present invention can use various kinds of hetero-substrates such as the III-nitride layer on the sapphire substrate, the silicon substrate, and the SiC substrate and so on. It is possible to grow the III-nitride ELO layer on the sapphire substrate with the growth restrict mask directly.

In another example, the present invention is described as being used to fabricate different opto-electronic device structures, such as a light-emitting diode (LED), laser diode (LD), photodiode (PD), Schottky barrier diode (SBD), or metal-oxide-semiconductor field-effect-transistor (MOSFET). The present invention may also be used to fabricate other opto-electronic devices, such as micro-LEDs, vertical cavity surface emitting lasers (VCSELs), edge-emitting laser diodes (EELDs), and solar cells.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method, comprising:
removing one or more devices from a substrate using an epitaxial lateral overgrowth (ELO) technique, by:
growing one or more coloring layers and device layers on a substrate with a growth restrict mask;
forming a bar comprised of the coloring layers and the device layers;
removing the bar from the substrate; and
eliminating at least a portion of at least one of the coloring layers from the bar.

2. The method of claim 1, wherein the substrate is a III-nitride-based substrate, a foreign substrate, or a hetero-substrate.

3. The method of claim 1, wherein a thickness of the coloring layers is less than about 18 µm.

4. The method of claim 1, wherein the coloring layers are grown directly on the growth restrict mask.

5. The method of claim 1, wherein adjacent ones of the coloring layers coalesce to each other.

6. The method of claim 5, wherein at least one of the coloring layers includes a void.

7. The method of claim 1, wherein growth of the coloring layers is stopped before adjacent ones of the coloring layers coalesce to each other.

8. A device fabricated by the method of claim 1.

9. A method, comprising:
performing an epitaxial lateral overgrowth (ELO) of a III-nitride layer to cover a growth restrict mask deposited on a substrate, wherein:
the III-nitride layer is grown with a low V/III ratio of less than 500 resulting in high-speed lateral growth as compared to low-speed vertical growth;
the III-nitride layer contains a large amount of impurities, over 1 × 10¹⁸ cm⁻³, which results in the III-nitride layer comprising a coloring layer;
the coloring layer absorbs light from an active region due to the large amount of impurities; and
at least part of the coloring layer is removed when a bar of device layers grown on the III-nitride layer is removed from the substrate, thereby reducing absorption losses.

10. A method, comprising:
realizing high-speed lateral growth of one or more III-nitride layers as compared to low-speed vertical growth, using an epitaxial lateral overgrowth (ELO) technique, wherein:
the high-speed lateral growth of the III-nitride layers results from a low V/III ratio growth condition of less than 500; and
the high-speed lateral growth of the III-nitride layers results in higher concentrations of impurities, over 1 × 10¹⁸ cm⁻³, in at least one of the III-nitride layers, which is a coloring layer.

11. The method of claim 10, wherein the higher concentrations of impurities in the III-nitride layers cause absorption and scattering of light generated in an active region.

12. The method of claim 10, wherein the high-speed lateral growth reduces a cost of a device, because of a decrease in growth time and source material used.

13. The method of claim 10, wherein the high-speed lateral growth suppresses vertical growth, which reduces an aspect ratio between a width and height of the III-nitride layers, thereby allowing for a thin device.

14. The method of claim 10, wherein the high-speed lateral growth reduces a side facet area and thus decreases an amount of light extracted from the side facet area.

15. The method of claim 10, wherein the high-speed lateral growth reduces fluctuations in a height of the III-nitride layers.

16. The method of claim 10, wherein the high-speed lateral growth permits wider periods between opening areas in a growth restrict mask deposited on a substrate without coalescence regions.
